(19) United States
(12) Patent Application Publication
(10) Pub. No.: US 2026/0161035 A1
(43) Pub. Date: Jun. 11, 2026

(54) ARRAY SUBSTRATE, DISPLAY PANEL, AND DISPLAY APPARATUS

(71) Applicants: CHENGDU BOE DISPLAY SCI-TECH CO., LTD., Sichuan (CN); BOE Technology Group Co., Ltd., Beijing (CN)

(72) Inventors: Cong ZHANG, Beijing (CN); Guidong YANG, Beijing (CN); Toshifumi YAGI, Beijing (CN); Yuanhui GUO, Beijing (CN); Jiajin LIU, Beijing (CN); Lei LIU, Beijing (CN); Junying XIAO, Beijing (CN)

(21) Appl. No.: 18/708,740

(22) PCT Filed: Jul. 31, 2023
(86) PCT No.: PCT/CN2023/110305

§ 371 Date: May 9, 2024

(51) Int. Cl. G02F 1/1368; G02F 1/1362; H10D 86/40; H10D 86/60

(52) U.S. Cl. CPC G02F 1/1368; G02F 1/136286; H10D 86/441; H10D 86/60

(57) ABSTRACT

Embodiments of the disclosure provide an array substrate, a display panel, and a display apparatus. The array substrate includes: a base substrate; and a plurality of sub-pixels located at one side of the base substrate. The plurality of sub-pixels include: sub-pixel rows extending in a first direction and arranged in a second direction. At least one of the sub-pixels includes: a main pixel portion and an auxiliary pixel portion that are distributed in the second direction. Brightness of the main pixel portion is greater than that of the auxiliary pixel portion. The main pixel portion and the auxiliary pixel portion are arranged in the sub-pixel row alternately.

### CROSS REFERENCE TO RELATED APPLICATIONS

This application is a national phase entry under 35 U.S.C. § 371 of International Application No. PCT/CN 2023/110305, filed on Jul. 31, 2023, the entire content of which is incorporated herein by reference.

### TECHNICAL FIELD

The disclosure relates to the technical field of semiconductors, and particularly relates to an array substrate, a display panel, and a display apparatus.

### BACKGROUND

A name of UV2A comes from multiplication of ultraviolet (UV) and vertical alignment (VA) of a liquid crystal panel. This technology can precisely control alignment of liquid crystal molecules through ultraviolet, which greatly improves light transmittance.

The key of the UV2A is to precisely control the liquid crystal molecules to tilt in an ultraviolet direction by using a special high-polymer material as an alignment film. Its precision unit is picometer (one trillionth of a meter). The UV2A has an advantage that the liquid crystal panel is of a simple structure without protrusions and slits. This “dream of liquid crystal technicians” was discussed as early as 30 years ago. It is only in recent times, with the availability of new materials, production equipment, and improved processing processes, that this dream has been realized. The simple construction of the liquid crystal panel not only enhances production efficiency but also offers many advantages in image quality.

High-resolution products, such as 8K and 16K display products, are the main focus for future products. However, current 8K vertical alignment (VA) liquid crystal products face challenges of low transmittance and poor color accuracy.

### SUMMARY

Embodiments of the disclosure provide an array substrate, a display panel, and a display apparatus. The array substrate includes: a base substrate; and a plurality of sub-pixels located on one side of the base substrate. The plurality of sub-pixels includes: sub-pixel rows extending in a first direction and arranged in a second direction. At least one of the sub-pixels includes: a main pixel portion and an auxiliary pixel portion that are distributed in the second direction. Brightness of the main pixel portion is greater than that of the auxiliary pixel portion, and the main pixel portion and the auxiliary pixel portion are arranged in the sub-pixel row alternately.

In a possible implementation, the array substrate includes: a gate line extending in the first direction, a data line extending in the second direction, a first common line distributed at one side of the gate line and extending in the first direction, and a second common line distributed at the other side of the gate line and extending in the first direction. The sub-pixel includes: a first sub-pixel electrode, a second sub-pixel electrode, a first transistor electrically connected with the first sub-pixel electrode, a second transistor electrically connected with the second sub-pixel electrode, and a third transistor electrically connected with one of the first transistor and the second transistor. The first sub-pixel electrode and the first common line are located at the same side of the gate line. The second sub-pixel electrode and the second common line are located at the same side of the gate line. Orthogonal projections of the third transistors of the plurality of sub-pixels on the base substrate are distributed in a first zone and a second zone alternately in the sub-pixel row. The first zone includes: the gate line, the first common line, and a zone between the gate line and the first common line. The second zone includes: the gate line, the second common line, and a zone between the gate line and the second common line.

In a possible implementation, the third transistors of the plurality of sub-pixels are electrically connected with the first common line and the second common line in the sub-pixel row alternately.

In a possible implementation, the first transistor includes: a first-transistor gate electrode, a first-transistor first electrode, and a first-transistor second electrode. The second transistor includes: a second-transistor gate electrode, a second-transistor first electrode, and a second-transistor second electrode. The third transistor includes: a third-transistor gate electrode, a third-transistor first electrode, and a third-transistor second electrode.

The first-transistor second electrodes and the second-transistor second electrodes of the plurality of sub-pixels are reused alternately as the third-transistor first electrodes in the sub-pixel row.

In a possible implementation, the plurality of first-transistor second electrodes include: first-type second electrodes and second-type second electrodes. The first-type second electrode includes: a first-type first part extending in the first direction, a first-type second part extending from one end of the first-type first part to a side of the gate line, and a first-type third part extending from the other end of the first-type first part to the side of the gate line. The second-type second electrode includes: a second-type first part extending in the first direction, and a second-type second part extending from one end of the second-type first part to one side of the gate line. The first-type second electrodes and the second-type second electrodes are distributed alternately in the sub-pixel row.

In a possible implementation, the second-transistor second electrodes include: third-type second electrodes and fourth-type second electrodes. The third-type second electrode includes: a third-type first part extending in the first direction, a third-type second part extending from one end of the third-type first part to a side of the gate line, and a third-type third part extending from the other end of the third-type first part to the side of the gate line. The fourth-type second electrode includes: a fourth-type first part extending in the first direction, and a fourth-type second part extending from one end of the fourth-type first part to the side of the gate line. The third-type second electrodes and the fourth-type second electrodes are distributed alternately in the sub-pixel row.

In a possible implementation, the first common line is provided with a first common convex portion facing a side of the gate line, and an orthogonal projection of the third-transistor second electrode on the base substrate and an orthogonal projection of the first common convex portion on the base substrate have an overlapping region. The second common line is provided with a second common convex portion facing the side of the gate line, and the orthogonal projection of the third-transistor second electrode on the base substrate and an orthogonal projection of the second common convex portion on the base substrate have an overlapping region. In the sub-pixel row, adjacent first common convex portions are spaced by one of the sub-pixels, adjacent second common convex portions are spaced by one of the sub-pixels, and the first common convex portion and the second common convex portion are distributed in a staggered manner.

In a possible implementation, the first sub-pixel electrode is of an integrated structure, and the second sub-pixel electrode is of an integrated structure.

In a possible implementation, the first sub-pixel electrode includes: a first electrode part and a second electrode part that are sequentially distributed in the second direction. The second sub-pixel electrode includes: a third electrode part and a fourth electrode part that are sequentially distributed in the second direction. The first electrode part is provided with a plurality of first slits. The second electrode part is provided with a plurality of second slits. The third electrode part is provided with a plurality of third slits. The fourth electrode part is provided with a plurality of fourth slits. An extending direction of the first slits is the same as that of the second slits. An extending direction of the third slits is the same as that of the fourth slits. The extending direction of the first slits is different from that of the third slits.

In a possible implementation, fifth slits are further provided between the first electrode part and the second electrode part, and an extending direction of the fifth slit is different from that of the first slit. Sixth slits are further provided between the third electrode part and the fourth electrode part, and an extending direction of the sixth slit is different from that of the third slits.

In a possible implementation, the fifth slit extends in the second direction, and the sixth slit extends in the second direction.

In a possible implementation, the extending direction of the fifth slit is the same as that of the third slit, and the extending direction of the sixth slit is the same as that of the first slit.

In a possible implementation, one side of the first electrode part facing the second electrode part is of a semi-closed structure, and one side of the second electrode part facing the first electrode part is of a semi-closed structure. A closed position of the first electrode part facing the second electrode part is opposite to an open position of the second electrode part facing the first electrode part. An open position of the first electrode part facing the second electrode part is opposite to a closed position of the second electrode part facing the first electrode part.

In a possible implementation, the first slit of the first electrode part is integrated with the second slit of the second electrode part. The third slit of the third electrode part is integrated with the fourth slit of the fourth electrode part.

In a possible implementation, the array substrate includes: a gate line extending in the first direction, a data line extending in the second direction, a first common line distributed at one side of the gate line, and a second common line distributed at the other side of the gate line. The sub-pixel includes: a first transistor, a second transistor, a third transistor electrically connected with one of the first transistor and the second transistor, and a first electrode part, a second electrode part, a third electrode part and a fourth electrode part that are sequentially distributed in the second direction. The first electrode part is electrically connected with one of the third electrode part and the fourth electrode part, such that a first connection sub-pixel electrode is formed. The second electrode part is electrically connected with the other of the third electrode part and the fourth electrode part, such that a second connection sub-pixel electrode is formed. In the sub-pixel row, the first connection sub-pixel electrodes of the plurality of sub-pixels are electrically connected with the first transistors and the second transistors alternately; and the second connection sub-pixel electrodes of the plurality of sub-pixels are electrically connected with the first transistors and the second transistors alternately. In the same sub-pixel, the first connection sub-pixel electrode and the second connection sub-pixel electrode are electrically connected with different transistors.

In a possible implementation, the first electrode part is electrically connected with the fourth electrode part, and the second electrode part is electrically connected with the third electrode part.

In a possible implementation, the array substrate further includes: first connecting parts and second connecting parts that extend in the second direction. One end of the first connecting part is electrically connected with the first electrode part, and the other end of the first connecting part is electrically connected with the fourth electrode part. One end of the second connecting part is electrically connected with the second electrode part, and the other end of the second connecting part is electrically connected with the third electrode part.

In a possible implementation, the array substrate further includes: first connecting convex portions connected with the first connecting part and protruding toward one side of the third transistor. In the sub-pixel row, the first connecting convex portions are electrically connected with the first transistors and the second transistors alternately.

In a possible implementation, extending lines of outer edges in the first direction of the first connecting convex portions adjacent in the sub-pixel row do not coincide with each other.

In a possible implementation, the first electrode part is electrically connected with the third electrode part, and the second electrode part is electrically connected with the fourth electrode part.

In a possible implementation, the array substrate further includes: third connecting parts and fourth connecting parts that extend in the second direction. An orthogonal projection of the third connecting part on the base substrate is located at one side of an orthogonal projection of the first sub-pixel electrode on the base substrate. One end of the third connecting part is electrically connected with the first electrode part, and the other end of the third connecting part is electrically connected with one side of the third electrode part facing the second electrode part. One end of the fourth connecting part is electrically connected with the second electrode part, and the other end of the fourth connecting part is electrically connected with the fourth electrode part.

In a possible implementation, the plurality of sub-pixels include: sub-pixel columns extending in the second direction and arranged in the first direction. The main pixel portions and the auxiliary pixel portions are arranged in the sub-pixel column alternately.

In a possible implementation, the plurality of sub-pixels include: sub-pixel columns extending in the second direction and arranged in the first direction. Two main pixel portions and two auxiliary pixel portions are arranged in the sub-pixel column alternately.

In a possible implementation, the array substrate further includes: a first electrode layer. The first electrode layer includes: a first electrode connecting part, a first hollowed-out structure, and a second hollowed-out structure. An orthogonal projection of the first hollowed-out structure on the base substrate at least partially overlaps with an orthogonal projection of the first sub-pixel electrode on the base substrate. An orthogonal projection of the second hollowed-out structure on the base substrate at least partially overlaps with an orthogonal projection of the second sub-pixel electrode on the base substrate.

In a possible implementation, an orthogonal projection of the first electrode connecting part on the base substrate covers an orthogonal projection of the data line on the base substrate.

Embodiments of the disclosure further provide a display panel. The display panel includes the array substrate according to the embodiment of the disclosure, and an opposing substrate arranged opposite the array substrate. One side of the opposing substrate facing the array substrate is provided with a common electrode layer.

In a possible implementation, a first electrode layer and the common electrode layer are provided with the same signal.

Embodiments of the disclosure further provide a display apparatus. The display apparatus includes the display panel according to the embodiment of the disclosure.

### BRIEF DESCRIPTION OF FIGURES

FIG. 1A is a first top view of an array substrate according to embodiments of the disclosure.

FIG. 1B is a schematic single-layer diagram of a gate line layer in FIG. 1A.

FIG. 1C is a schematic single-layer diagram of an active layer in FIG. 1A.

FIG. 1D is a schematic single-layer diagram of a data line layer in FIG. 1A.

FIG. 1E is a schematic single-layer diagram of a first insulation layer in FIG. 1A.

FIG. 1F is a schematic single-layer diagram of a pixel electrode layer in FIG. 1A.

FIG. 1G is a schematic diagram showing light effect simulation corresponding to the array substrate in FIG. 1A.

FIG. 1H is a sectional view along line EF in FIG. 1A.

FIG. 2A is a second top view of an array substrate according to embodiments of the disclosure.

FIG. 2B is a schematic single-layer diagram of a gate line layer in FIG. 2A.

FIG. 2C is a schematic single-layer diagram of an active layer in FIG. 2A.

FIG. 2D is a schematic single-layer diagram of a data line layer in FIG. 2A.

FIG. 2E is a schematic single-layer diagram of a first insulation layer in FIG. 2A.

FIG. 2F is a schematic single-layer diagram of a pixel electrode layer in FIG. 2A.

FIG. 2G is a schematic diagram showing light effect simulation corresponding to an array substrate in FIG. 2A.

FIG. 3A is a third top view of an array substrate according to embodiments of the disclosure.

FIG. 3B is a schematic single-layer diagram of a gate line layer in FIG. 3A.

FIG. 3C is a schematic single-layer diagram of an active layer in FIG. 3A.

FIG. 3D is a schematic single-layer diagram of a data line layer in FIG. 3A.

FIG. 3E is a schematic single-layer diagram of a first insulation layer in FIG. 3A.

FIG. 3F is a schematic single-layer diagram of a pixel electrode layer in FIG. 3A.

FIG. 3G is a schematic diagram showing light effect simulation corresponding to an array substrate in FIG. 3A.

FIG. 4A is a fourth top view of an array substrate according to embodiments of the disclosure.

FIG. 4B is a schematic single-layer diagram of a gate line layer in FIG. 4A.

FIG. 4C is a schematic single-layer diagram of an active layer in FIG. 4A.

FIG. 4D is a schematic single-layer diagram of a data line layer in FIG. 4A.

FIG. 4E is a schematic single-layer diagram of a first insulation layer in FIG. 4A.

FIG. 4F is a schematic single-layer diagram of a pixel electrode layer in FIG. 4A.

FIG. 4G is a schematic diagram showing light effect simulation corresponding to an array substrate in FIG. 4A.

FIG. 5A is a fifth top view of an array substrate according to embodiments of the disclosure.

FIG. 5B is a schematic single-layer diagram of a gate line layer in FIG. 5A.

FIG. 5C is a schematic single-layer diagram of an active layer in FIG. 5A.

FIG. 5D is a schematic single-layer diagram of a data line layer in FIG. 5A.

FIG. 5E is a schematic single-layer diagram of a first insulation layer in FIG. 5A.

FIG. 5F is a schematic single-layer diagram of a pixel electrode layer in FIG. 5A.

FIG. 5G is a schematic diagram showing light effect simulation corresponding to an array substrate in FIG. 5A.

FIG. 6A is a sixth top view of an array substrate according to embodiments of the disclosure.

FIG. 6B is a schematic single-layer diagram of a gate line layer in FIG. 6A.

FIG. 6C is a schematic single-layer diagram of an active layer in FIG. 6A.

FIG. 6D is a schematic single-layer diagram of a data line layer in FIG. 6A.

FIG. 6E is a schematic single-layer diagram of first insulation layer in FIG. 6A.

FIG. 6F is a schematic single-layer diagram of a pixel electrode layer in FIG. 6A.

FIG. 7 is a seventh top view of an array substrate according to embodiments of the disclosure.

FIG. 8 is an eighth top view of an array substrate according to embodiments of the disclosure.

FIG. 9A is a ninth top view of an array substrate according to embodiments of the disclosure.

FIG. 9B is a schematic single-layer diagram of a gate line layer in FIG. 9A.

FIG. 9C is a schematic single-layer diagram of an active layer in FIG. 9A.

FIG. 9D is a schematic single-layer diagram of a data line layer in FIG. 9A.

FIG. 9E is a schematic single-layer diagram of a first insulation layer in FIG. 9A.

FIG. 9F is a schematic single-layer diagram of a first electrode layer in FIG. 9A.

FIG. 9G is a schematic single-layer diagram of a second insulation layer in FIG. 9A.

FIG. 9H is a schematic single-layer diagram of a pixel electrode layer in FIG. 9A.

FIG. 9I is a schematic diagram of a black matrix corresponding to an array substrate in FIG. 9A.

FIG. 9J is a schematic diagram showing light effect simulation corresponding to an array substrate in FIG. 9A.

FIG. 10 is a schematic diagram of a sub-pixel equivalent circuit according to embodiments of the disclosure.

FIG. 11 is a sectional view of a display panel according to an embodiment of the disclosure.

### DETAILED DESCRIPTION

For making objectives, technical solutions and advantages of embodiments of the disclosure clearer, the technical solutions of the embodiments of the disclosure will be clearly and completely described below in conjunction with the accompanying drawings in the embodiments of the disclosure. Apparently, the embodiments described are some embodiments rather than all embodiments of the disclosure. Based on the embodiments of the disclosure, all other embodiments obtained by those of ordinary skill in the art without making creative efforts fall within the scope of protection of the disclosure.

Unless otherwise defined, technical or scientific terms used in the disclosure should have ordinary meanings as understood by those of ordinary skill in the art to which the disclosure belongs. “First”, “second”, and other similar words used in the disclosure do not indicate any order, amount or importance, but are only used to distinguish different components. “Include”, “comprise”, “involve” and other similar words indicate that elements or objects before the word include elements or objects after the word and their equivalents, without excluding other elements or objects. “Connect”, “connected”, and other similar words are not limited to physical or mechanical connections, but may include electrical connections, which may be direct or indirect. “Upper”, “lower”, “left” and “right” are only used to indicate a relative positional relation. After an absolute position of the described object changes, the relative positional relation may also change accordingly.

“Approximately” or “substantially the same” used herein includes a stated value and means that the value is within a deviation range that is acceptable to a specific value and is determined by those of ordinary skill in the art in consideration of related errors (that is, limitations of measurement systems) between described measurement and specific quantity measurement. For example, “substantially the same” may mean that a difference from the stated value is within one or more standard deviation ranges, or within ranges of ±30%, 20%, 10%, and 5%.

In the drawings, thicknesses of layers, films, panels, zones, etc. are enlarged for clarity. Illustrative implementations are described herein with reference to a sectional view regarded as a schematic diagram of an idealized implementation. In this way, deviations between shapes of results caused by, for example, manufacturing technologies and/or tolerances and shapes in the drawing will be anticipated. Therefore, the implementations described herein should be interpreted as being not limited to specific shapes of zones as shown herein, but including deviations in shapes caused by, for example, manufacturing. For example, zones illustrated or described as flat can typically have rough and/or nonlinear features. Further, a sharp corner shown may be circular. Therefore, the zones illustrated in the figures are schematic in nature, and their shapes are not intended to illustrate exact shapes of the zones, and are not intended to limit the scope of the claims.

To keep the following description of the embodiments of the disclosure clear and concise, detailed description of known functions and components is omitted in the disclosure.

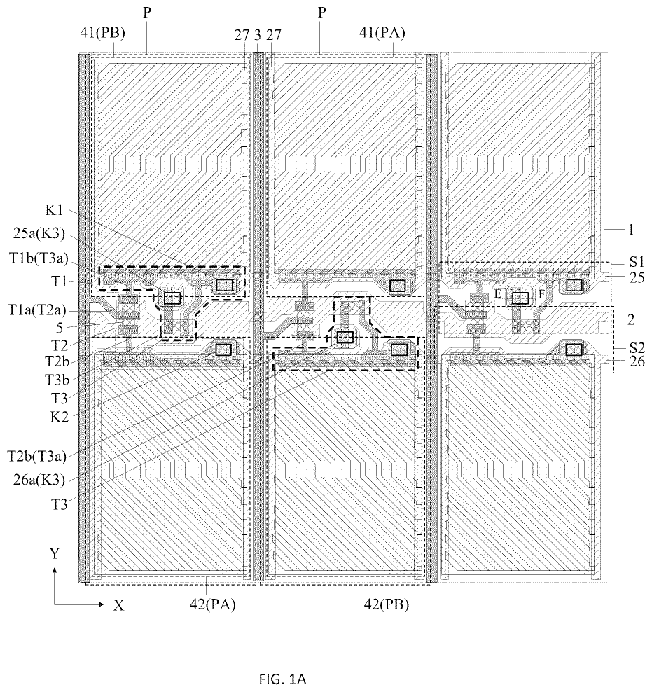

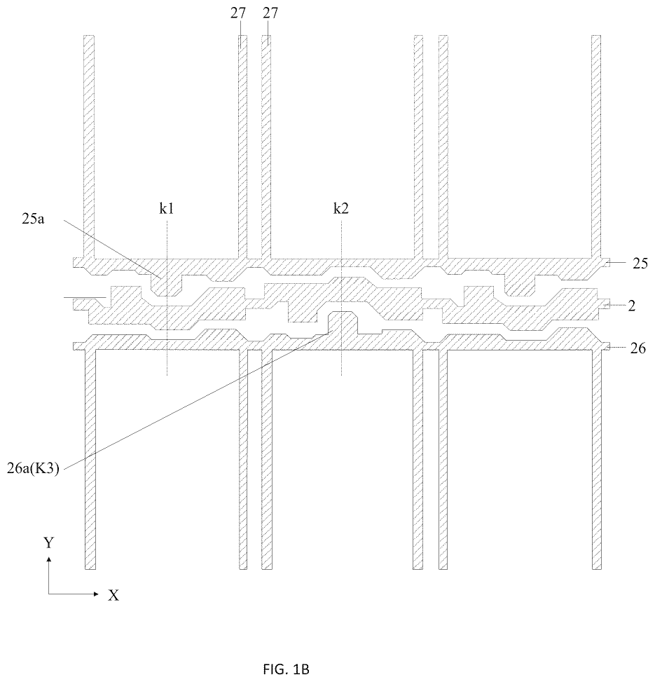

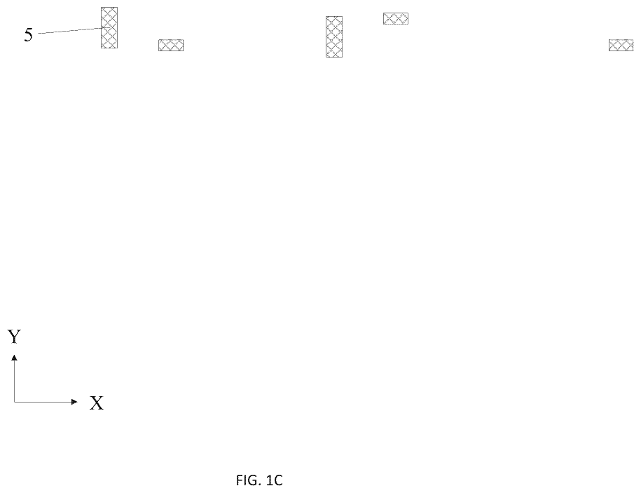

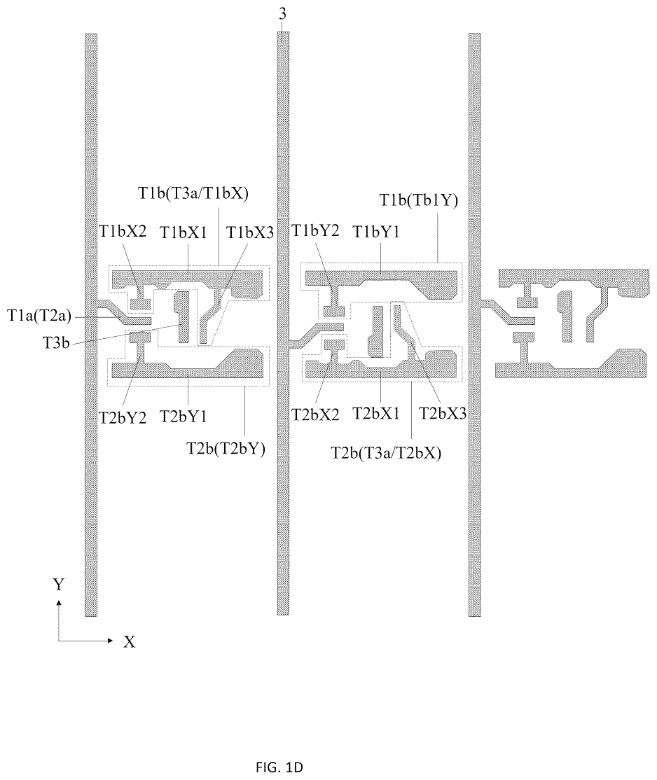

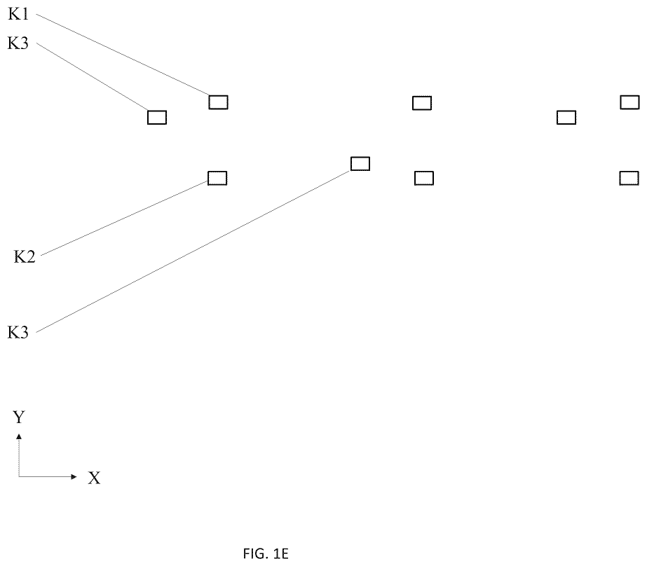

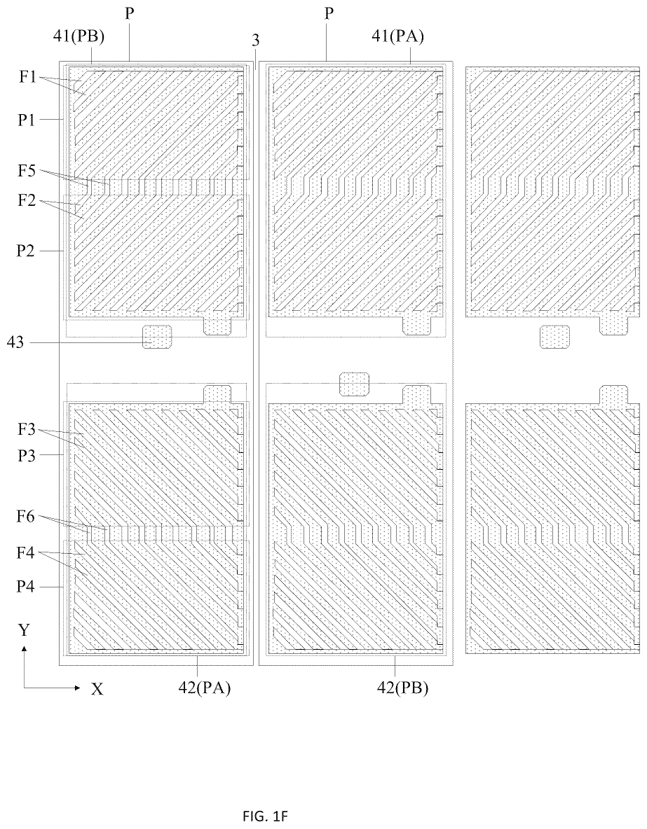

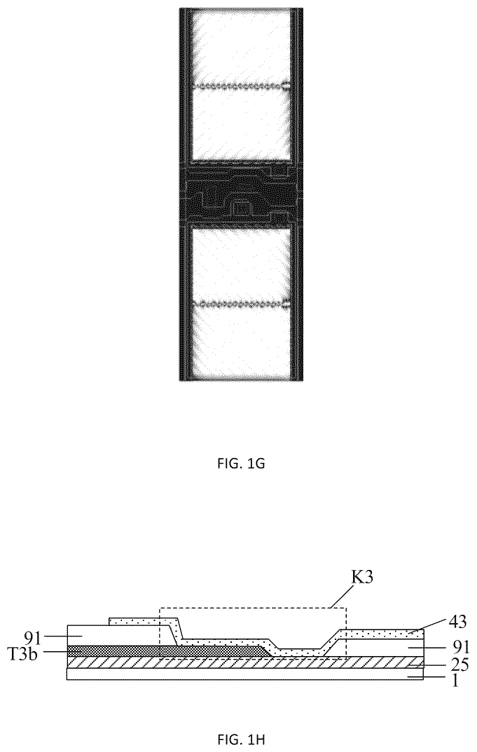

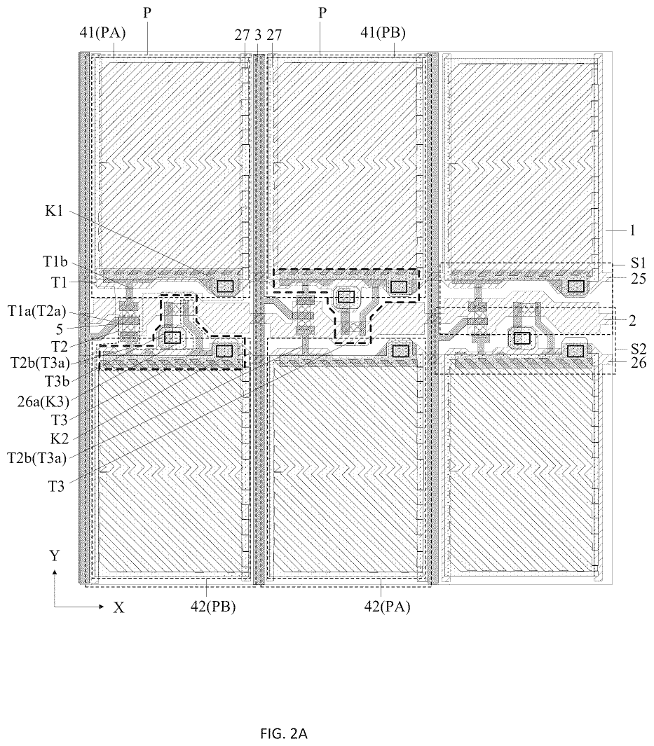

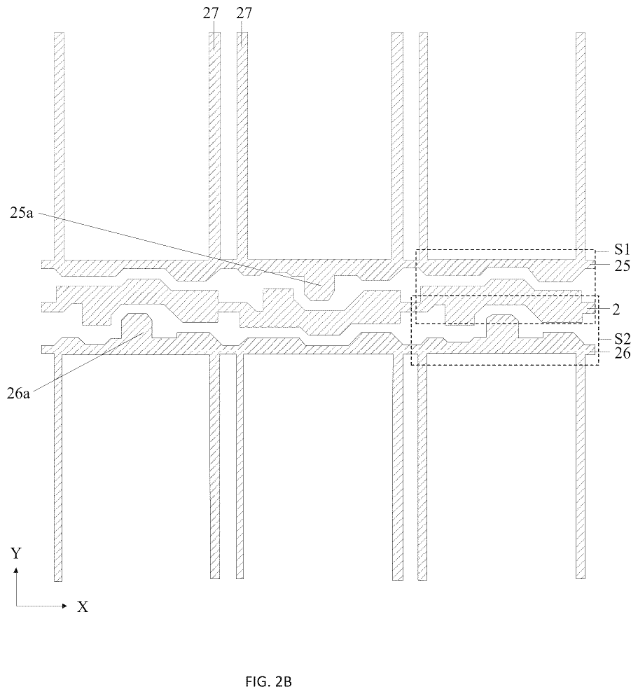

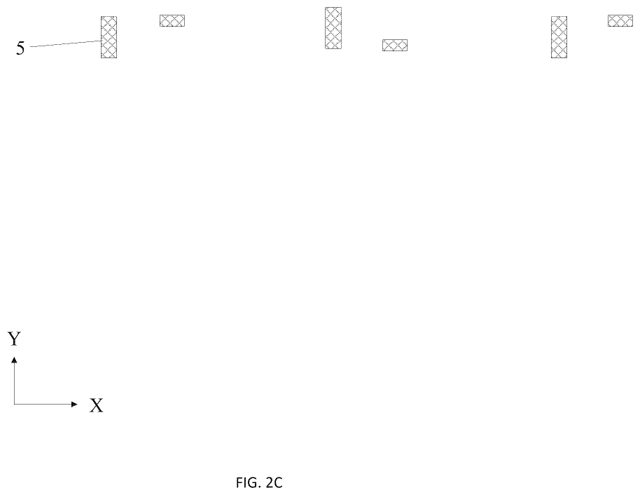

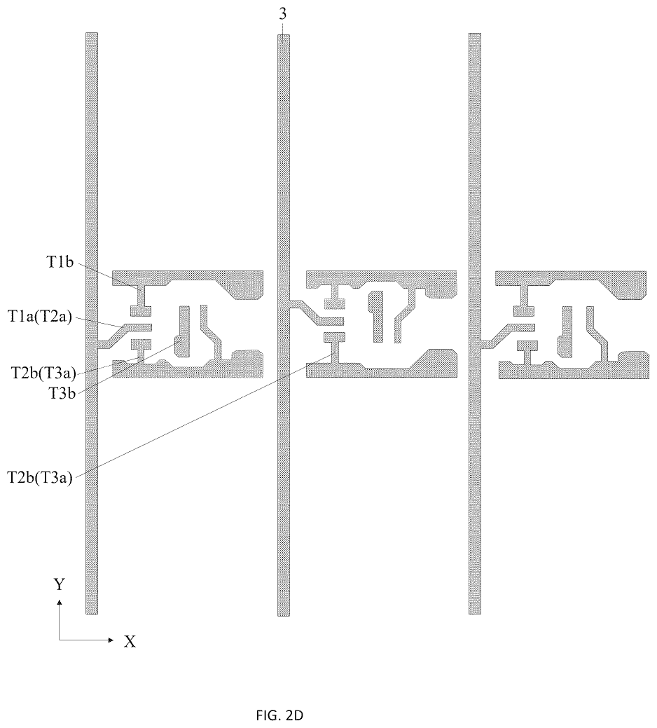

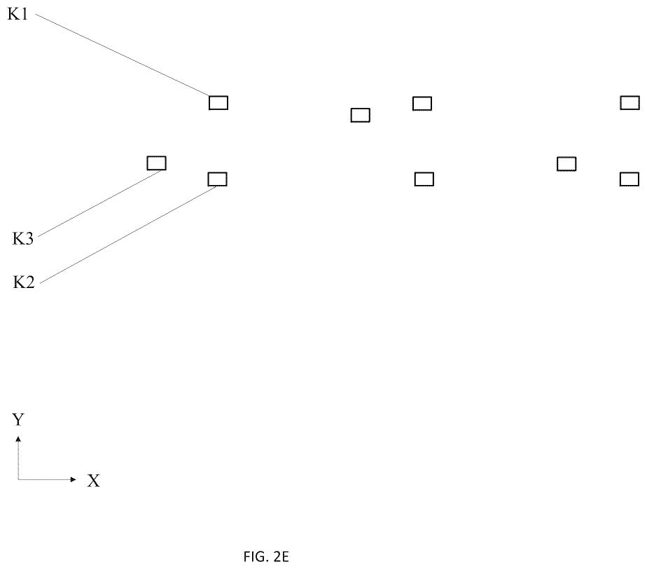

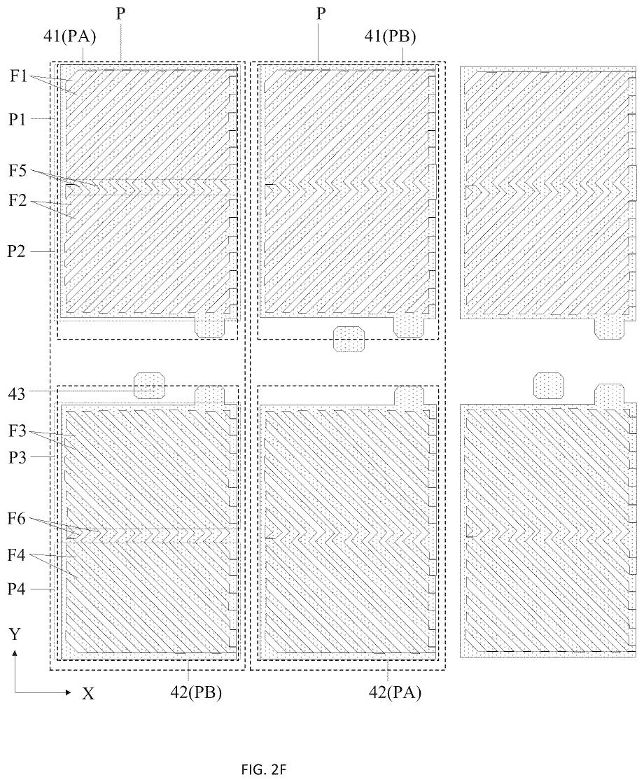

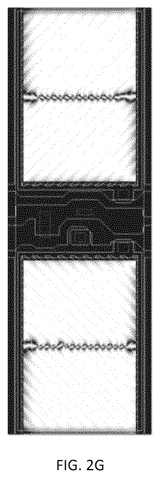

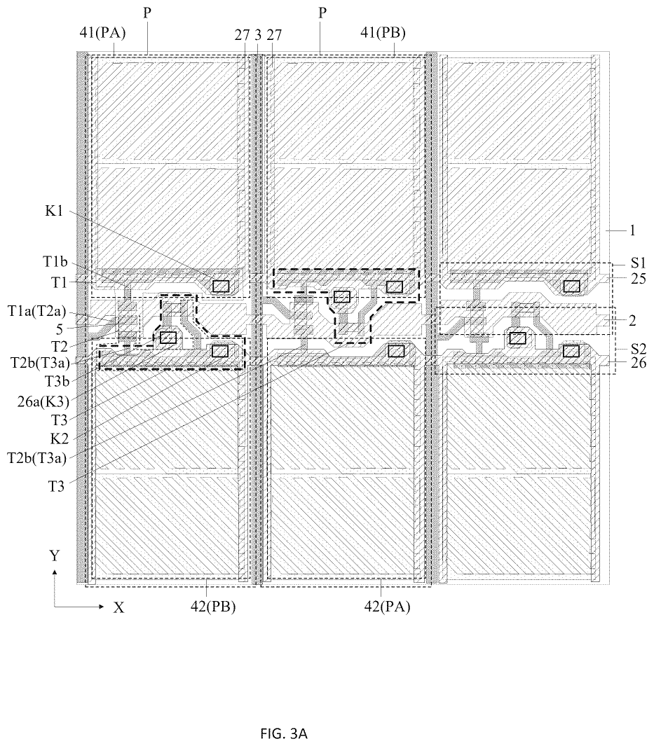

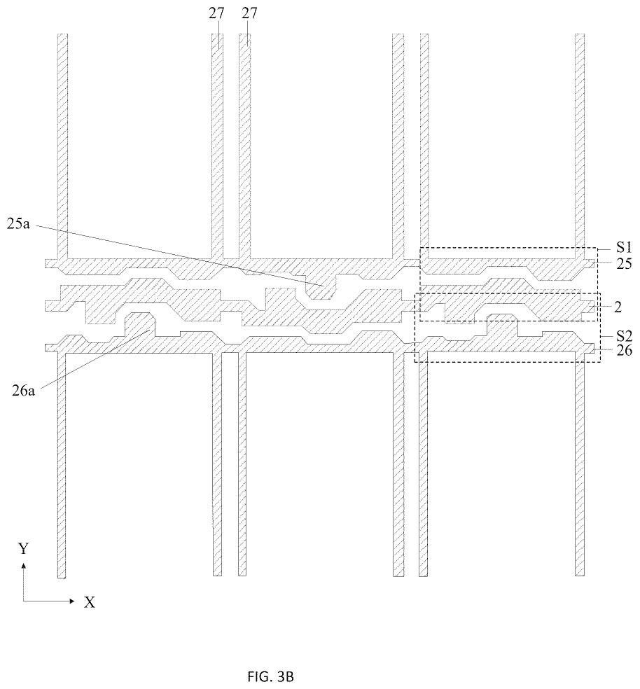

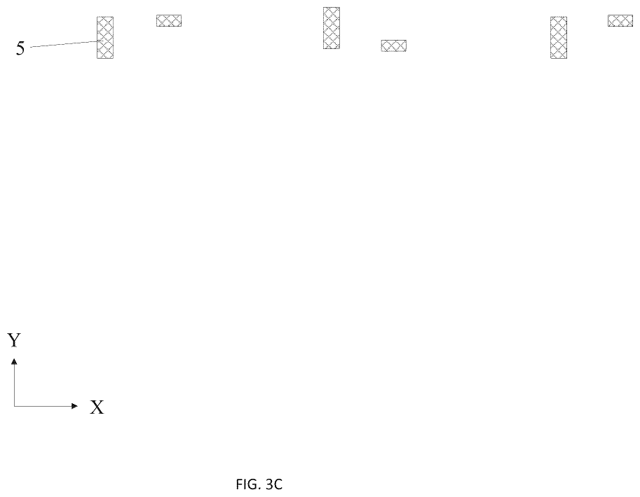

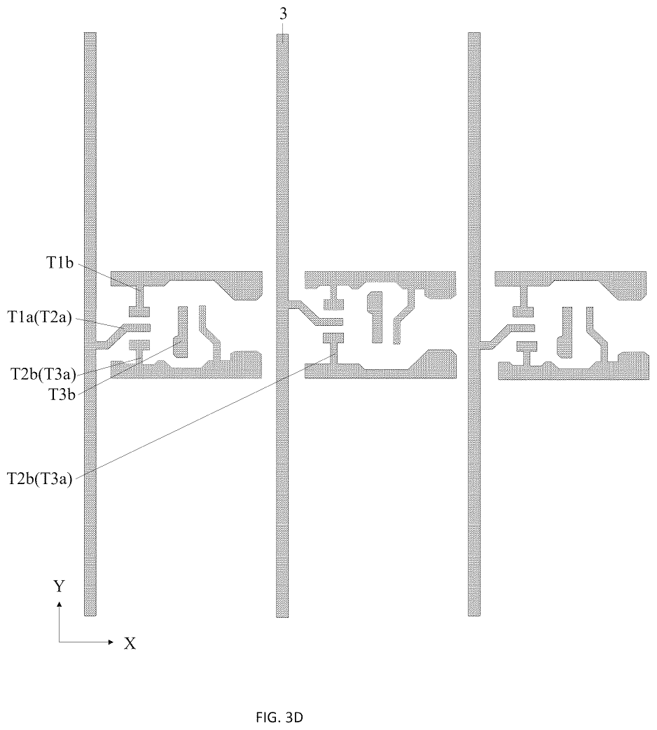

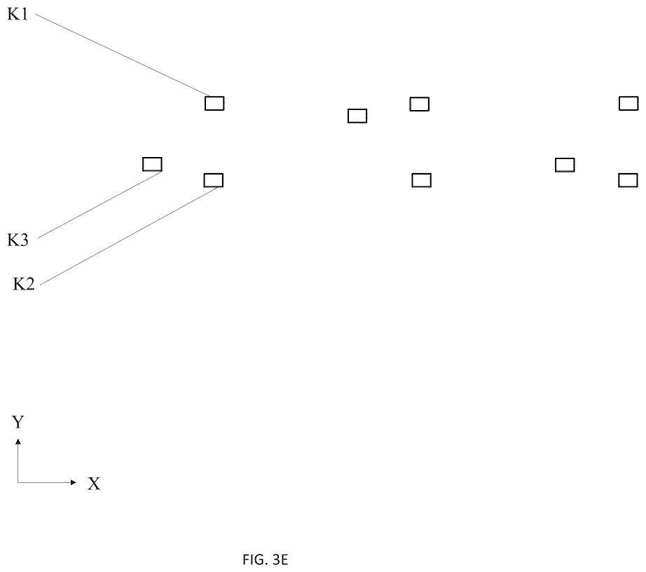

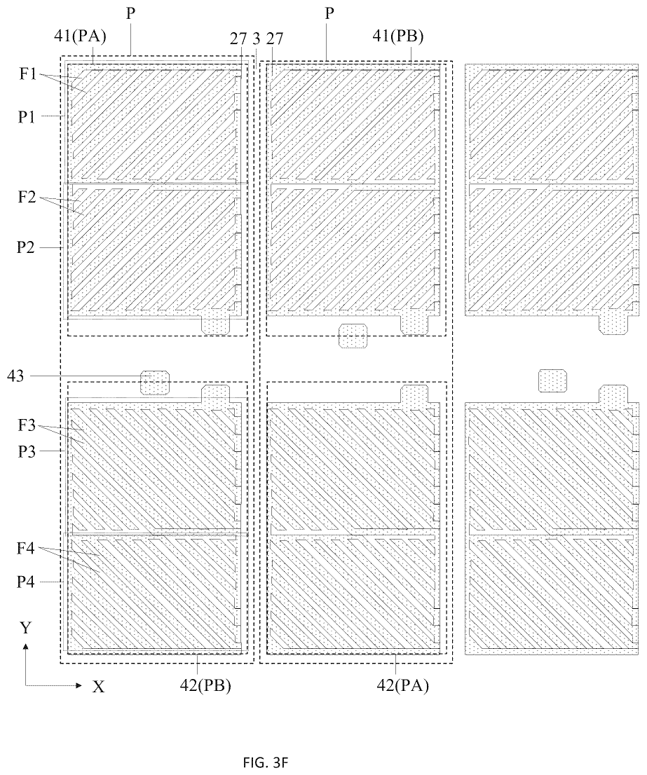

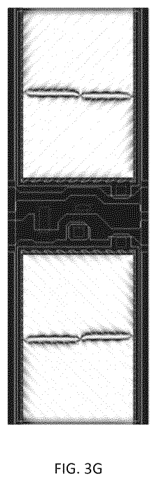

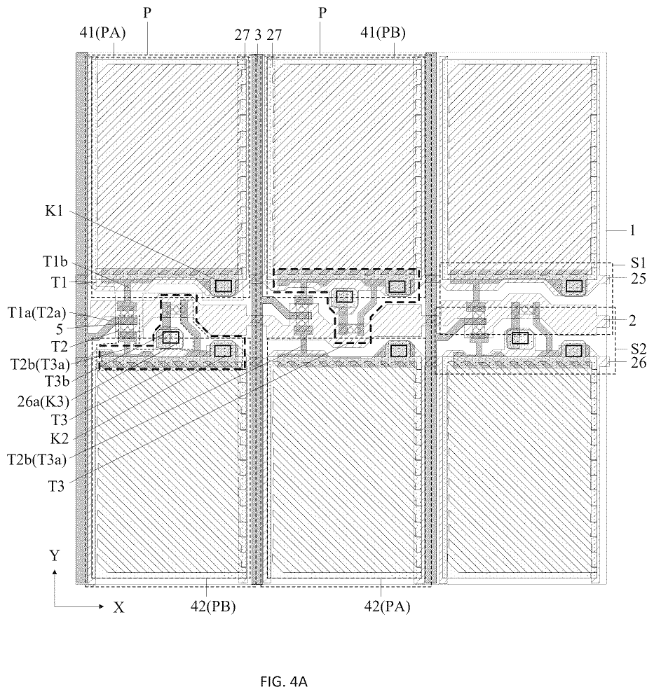

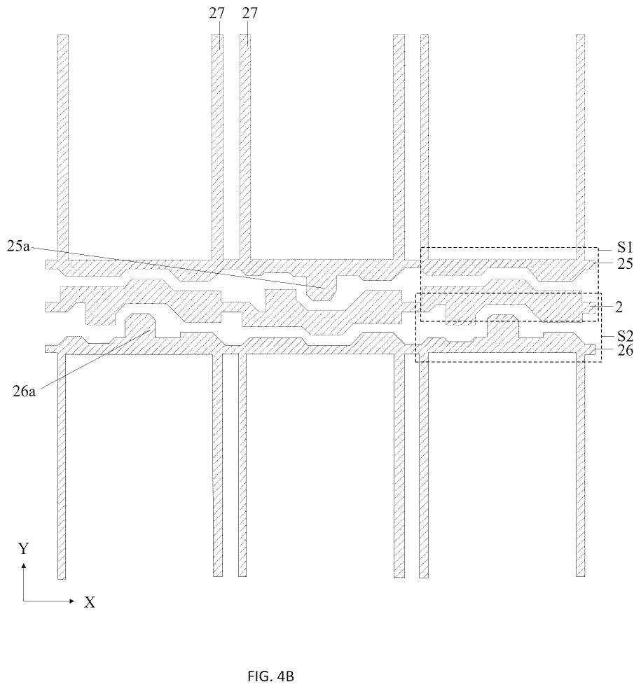

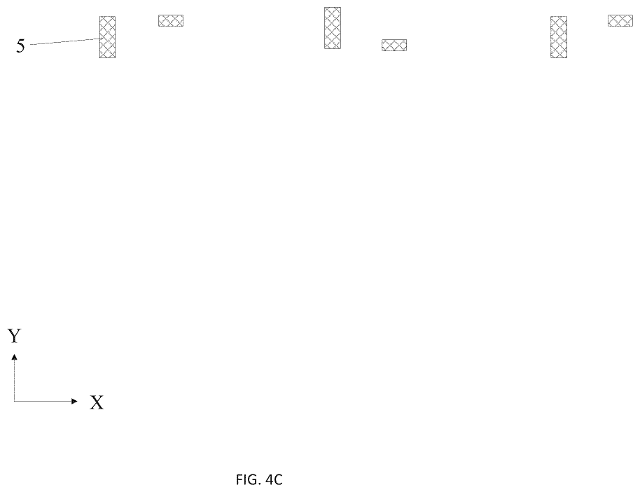

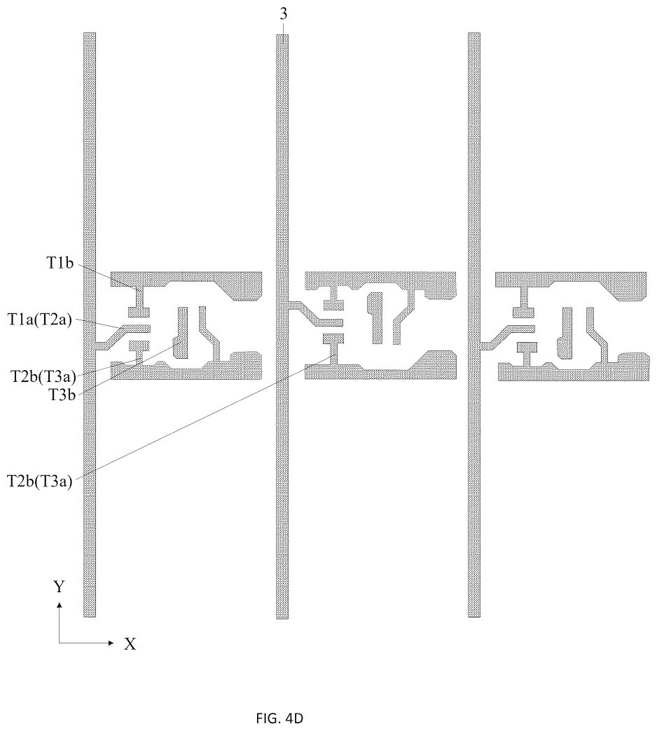

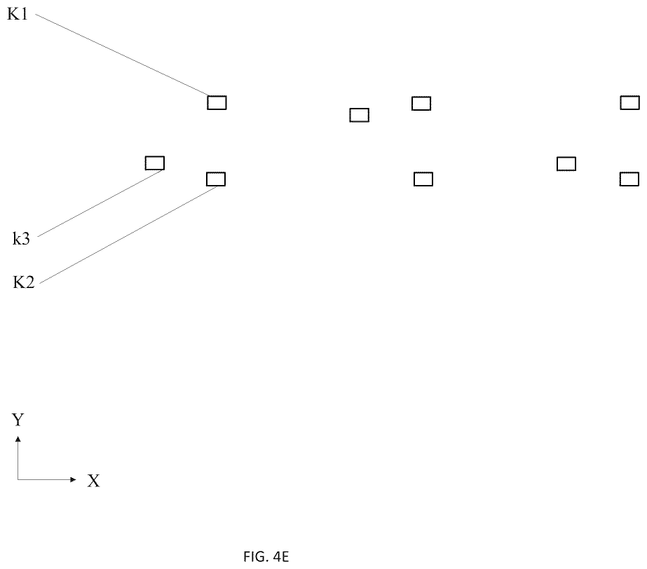

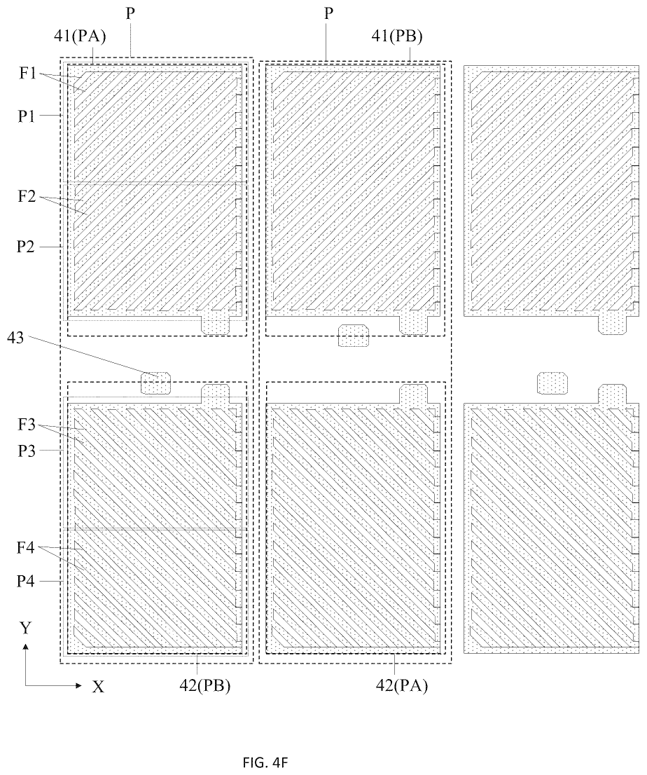

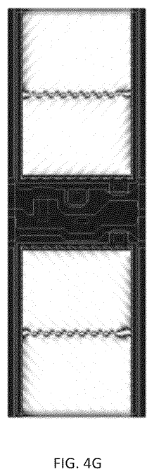

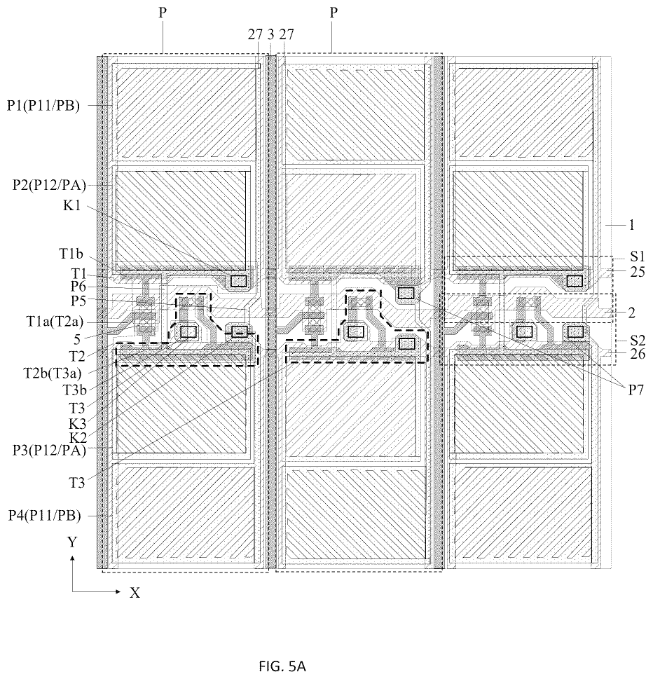

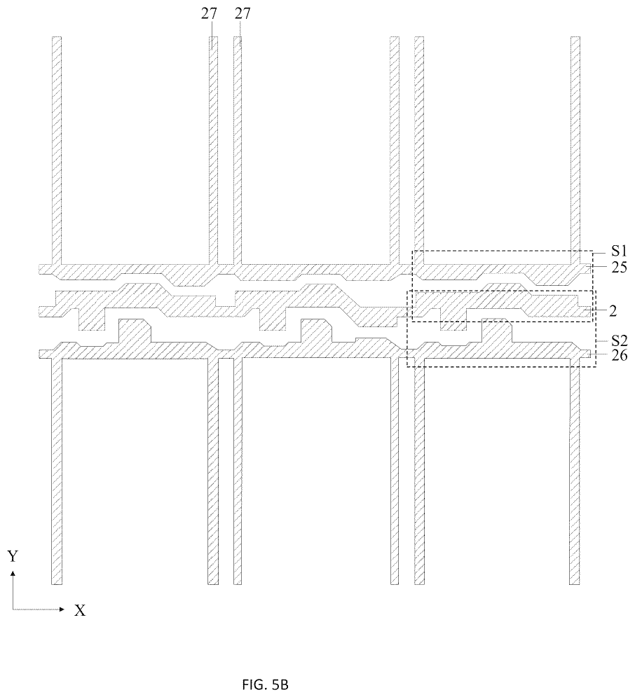

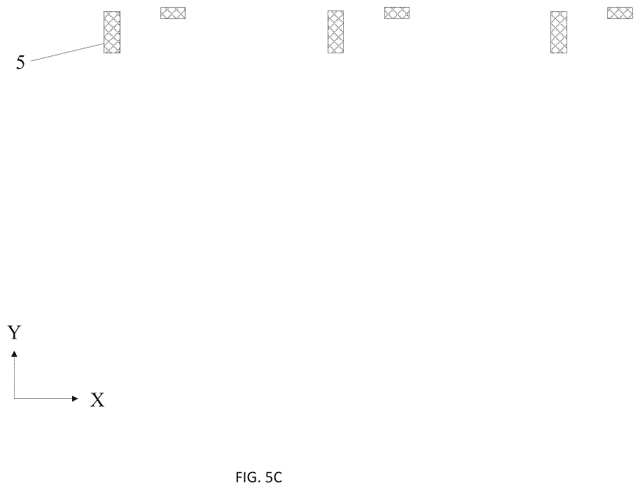

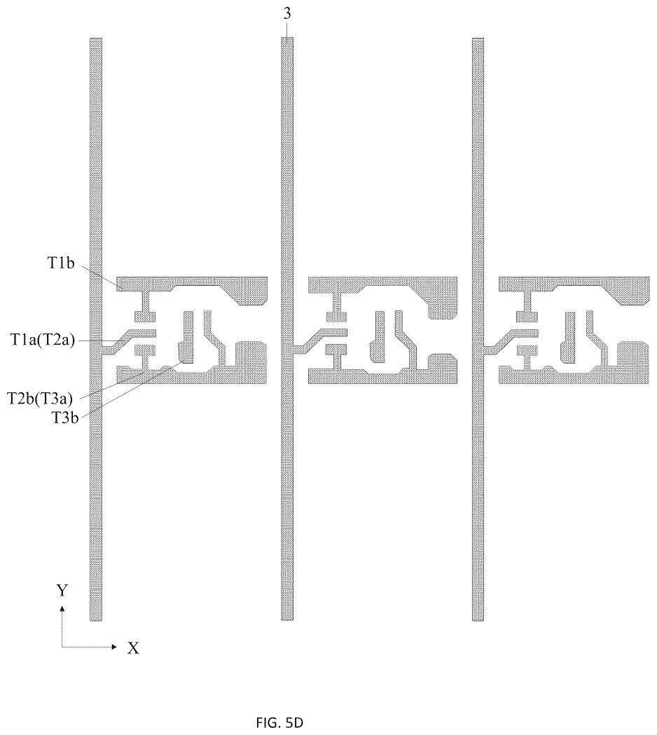

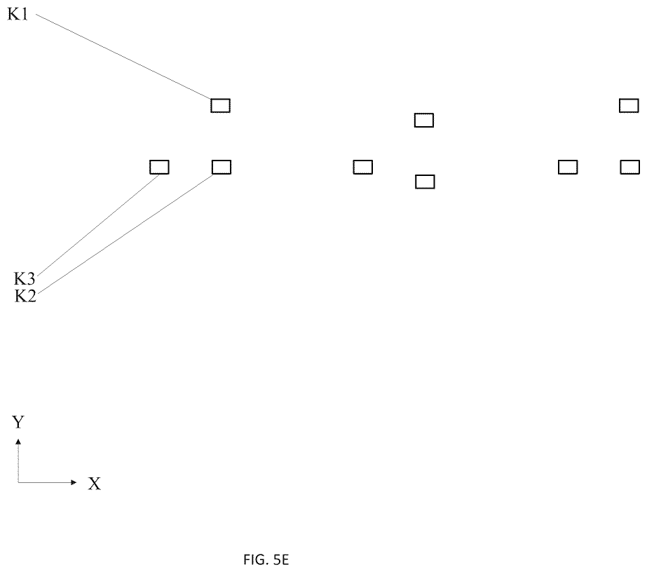

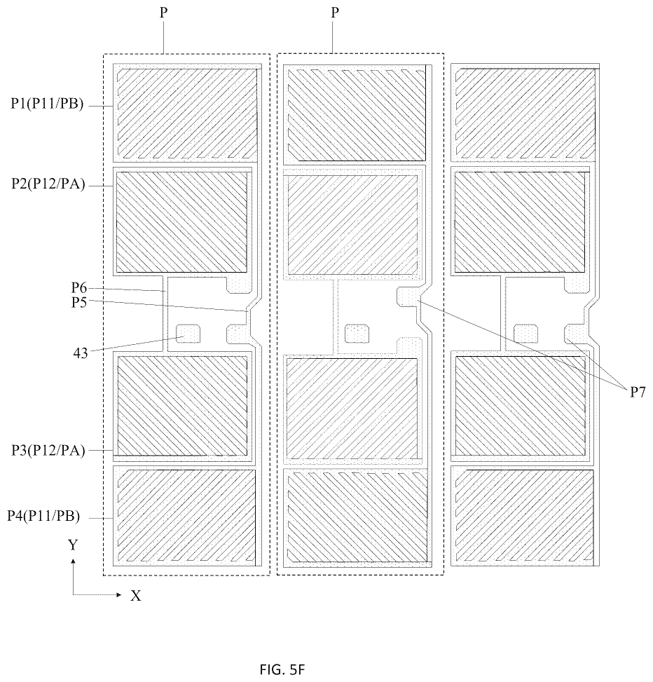

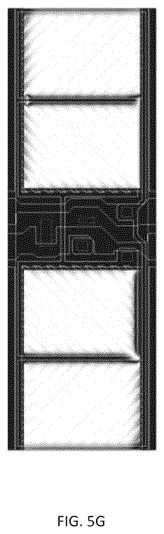

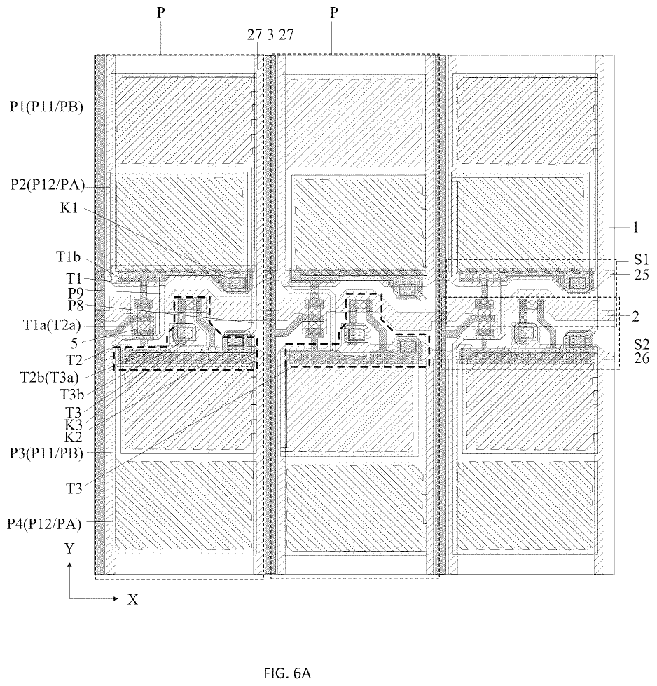

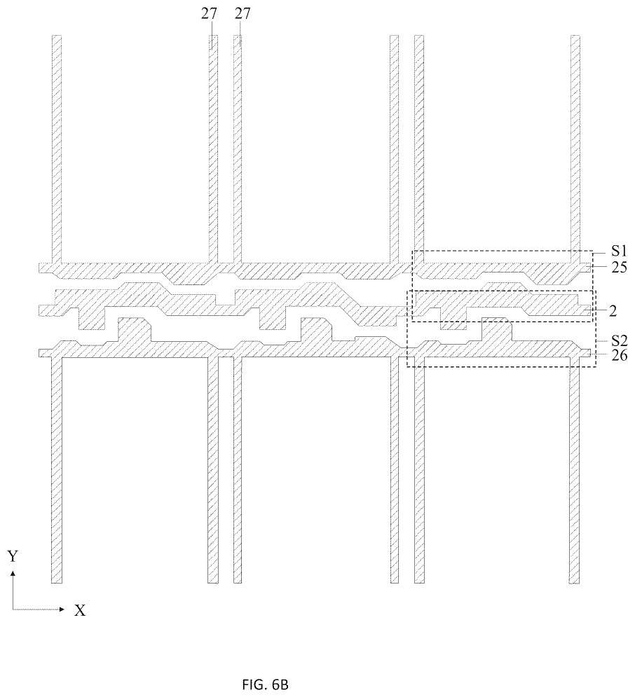

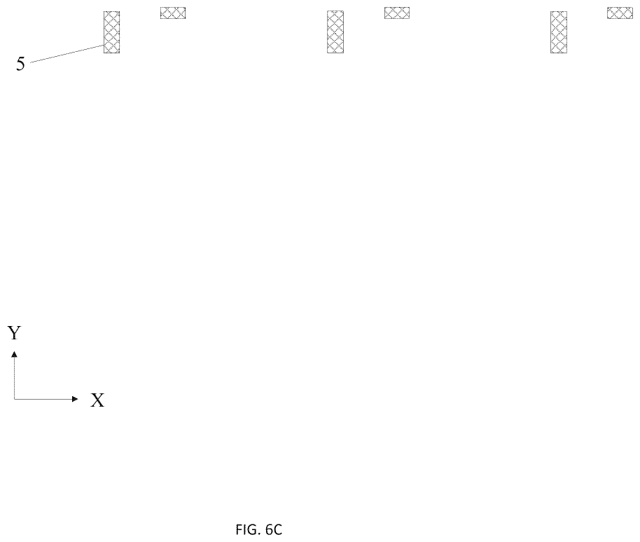

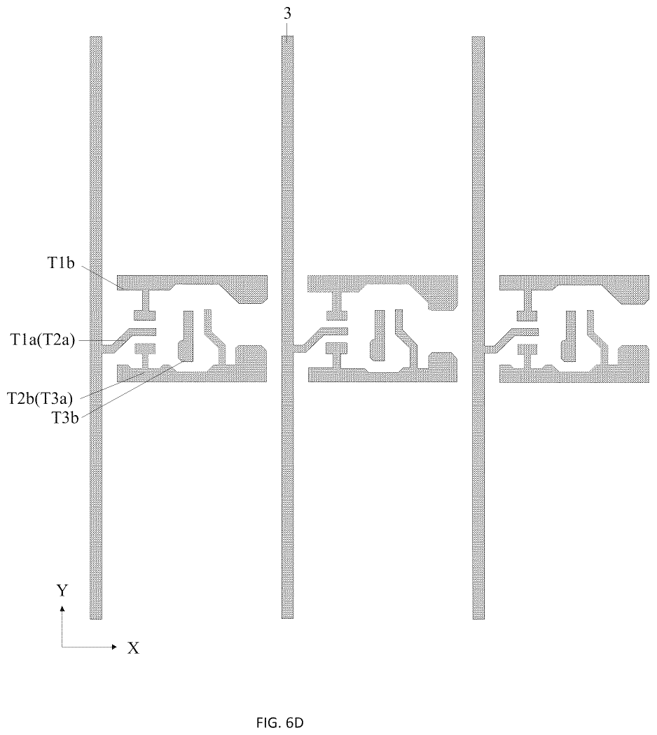

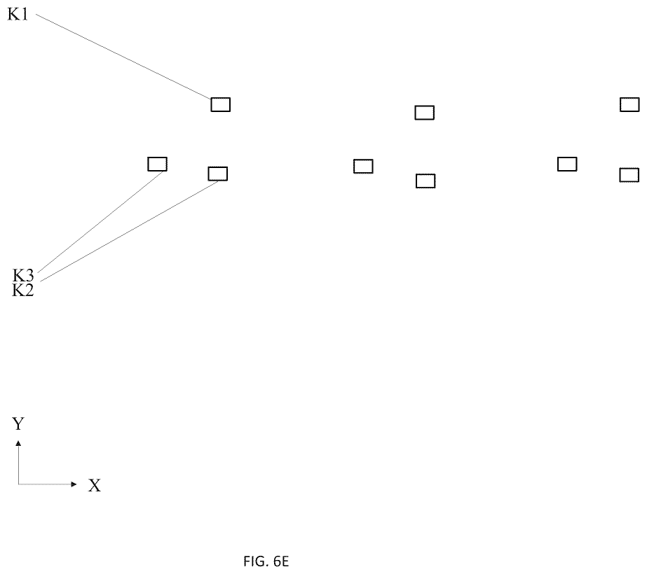

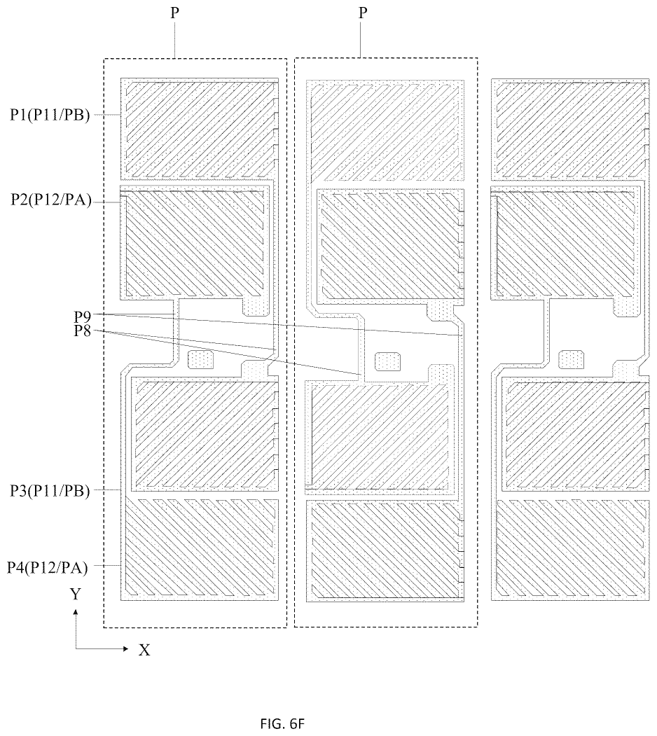

With reference to FIGS. 1A-1F, 2A-2F, 3A-3F, 4A-4F, 5A-5F, and 6A-6F, FIG. 1A is a first top view of an array substrate according to embodiments of the disclosure, FIG. 1B is a schematic single-layer diagram of a gate line layer in FIG. 1A, FIG. 1C is a schematic single-layer diagram of an active layer in FIG. 1A, FIG. 1D is a schematic single-layer diagram of a data line layer in FIG. 1A, FIG. 1E is a schematic single-layer diagram of a first insulation layer in FIG. 1A, FIG. 1F is a schematic single-layer diagram of a pixel electrode layer in FIG. 1A; FIG. 2A is a second top view of an array substrate according to embodiments of the disclosure, FIG. 2B is a schematic single-layer diagram of a gate line layer in FIG. 2A, FIG. 2C is a schematic single-layer diagram of an active layer in FIG. 2A, FIG. 2D is a schematic single-layer diagram of a data line layer in FIG. 2A, FIG. 2E is a schematic single-layer diagram of a first insulation layer in FIG. 2A, FIG. 2F is a schematic single-layer diagram of a pixel electrode layer in FIG. 2A; FIG. 3A is a third top view of an array substrate according to embodiments of the disclosure, FIG. 3B is a schematic single-layer diagram of a gate line layer in FIG. 3A, FIG. 3C is a schematic single-layer diagram of an active layer in FIG. 3A, FIG. 3D is a schematic single-layer diagram of a data line layer in FIG. 3A, FIG. 3E is a schematic single-layer diagram of a first insulation layer in FIG. 3A, FIG. 3F is a schematic single-layer diagram of a pixel electrode layer in FIG. 3A; FIG. 4A is a fourth top view of an array substrate according to embodiments of the disclosure, FIG. 4B is a schematic single-layer diagram of a gate line layer in FIG. 4A, FIG. 4C is a schematic single-layer diagram of an active layer in FIG. 4A, FIG. 4D is a schematic single-layer diagram of a data line layer in FIG. 4A, FIG. 4E is a schematic single-layer diagram of a first insulation layer in FIG. 4A, FIG. 4F is a schematic single-layer diagram of a pixel electrode layer in FIG. 4A; FIG. 5A is a fifth top view of an array substrate according to embodiments of the disclosure, FIG. 5B is a schematic single-layer diagram of a gate line layer in FIG. 5A, FIG. 5C is a schematic single-layer diagram of an active layer in FIG. 5A, FIG. 5D is a schematic single-layer diagram of a data line layer in FIG. 5A, FIG. 5E is a schematic single-layer diagram of a first insulation layer in FIG. 5A, FIG. 5F is a schematic single-layer diagram of a pixel electrode layer in FIG. 5A; FIG. 6A is a sixth top view of an array substrate according to embodiments of the disclosure, FIG. 6B is a schematic single-layer diagram of a gate line layer in FIG. 6A, FIG. 6C is a schematic single-layer diagram of an active layer in FIG. 6A, FIG. 6D is a schematic single-layer diagram of a data line layer in FIG. 6A, FIG. 6E is a schematic single-layer diagram of a first insulation layer in FIG. 6A, and FIG. 6F is a schematic single-layer diagram of a pixel electrode layer in FIG. 6A. Embodiments of the disclosure provide an array substrate. The array substrate includes:
A Base Substrate 1; and
a plurality of sub-pixels P disposed on a side of the base substrate 1. The plurality of sub-pixels P include: sub-pixel rows extending in a first direction X and arranged in a second direction Y. At least one of the sub-pixels P includes: a main pixel portion PA and an auxiliary pixel portion PB that are distributed in the second direction Y. Brightness of the main pixel portion PA is greater than that of the auxiliary pixel portion PB. The main pixel portion PA and the auxiliary pixel portion PB are arranged in the sub-pixel row alternately.

In the embodiments of the disclosure, at least one of the sub-pixels P includes: the main pixel portion PA and the auxiliary pixel portion PB that are distributed in the second direction Y. The brightness of the main pixel portion PA is greater than that of the auxiliary pixel portion PB. The main pixel portion PA and the auxiliary pixel portion PB are arranged in the sub-pixel row alternately. That is, the main pixel portion PA and the auxiliary pixel portion PB are separated in a vertical direction and staggered. Two sub-pixels in the first direction X may achieve a two-sub-pixel and eight-domain (2P8D) effect of bright-dark compensation, and meanwhile, two sub-pixels in the second direction Y may achieve an effect of bright-dark compensation. Moreover, two sub-pixels in the first direction X may achieve an effect of viewing-angle compensation, and meanwhile, two sub-pixels in the second direction Y may achieve an effect of viewing-angle compensation. The design of 2P8D can achieve an effect of both improving transmittance and avoiding color cast.

It may be understood that the brightness of the main pixel portion PA is greater than that of the auxiliary pixel portion PB, which indicates brightness comparison in one sub-pixel P when a display panel is powered on.

In a possible implementation, with reference to FIGS. 1A-1F, 2A-2F, 3A-3F, and 4A-4F, the array substrate includes: a gate line 2 extending in the first direction X, a data line 3 extending in the second direction Y, a first common line 25 distributed at one side of the gate line 2 and extending in the first direction X, and a second common line 26 distributed on the other side of the gate line 2 and extending in the first direction X. The sub-pixel includes: a first sub-pixel electrode 41, a second sub-pixel electrode 42, a first transistor T1 electrically connected with the first sub-pixel electrode 41, a second transistor T2 electrically connected with the second sub-pixel electrode, and a third transistor T3 electrically connected with one of the first transistor T1 and the second transistor T2. The first sub-pixel electrode 41 and the first common line 25 are located at the same side of the gate line 2, and the second sub-pixel electrode 42 and the second common line 26 are located at the same side of the gate line 2. For example, in FIG. 1A, the first sub-pixel electrode 41 and the first common line 25 are both located at an upper side of the gate line 2, and the second sub-pixel electrode 42 and the second common line 26 are both located at a lower side of the gate line 2. Orthogonal projections of the third transistors T3 of the plurality of sub-pixels P on the base substrate 1 are distributed in a first zone S1 and a second zone S2 alternately in the sub-pixel row. The first zone S1 includes: the gate line 2, the first common line 25, and a zone between the gate line 2 and the first common line 25. The second zone S2 includes: the gate line 2, the second common line 26, and a zone between the gate line 2 and the second common line 26.

In the embodiments of the disclosure, the orthogonal projections of the third transistors T3 of the plurality of sub-pixels P on the base substrate 1 are distributed in the first zone S1 and the second zone S2 alternately. In this way, the third transistors T3 may be electrically connected with the first common line 25 and the second common line 26 alternately, and further the main pixel portions PA and the auxiliary pixel portions PB may be arranged alternately.

Specifically, an orthogonal projection of the first transistor T1 on the base substrate 1 may be distributed in the first zone S1 (the first zone S1 may include: the gate line 2, the first common line 25, and the zone between the gate line 2 and the first common line 25). That is, the orthogonal projection of the first transistor T1 on the base substrate 1 may overlap with an orthogonal projection of the gate line 2 on the base substrate 1, with an orthogonal projection of the first common line 25 on the base substrate 1, and with an orthogonal projection of the zone between the gate line 2 and the first common line 25 on the base substrate 1. An orthogonal projection of the second transistor T2 on the base substrate 1 may be distributed in the second zone S2 (the second zone S2 may include: the gate line 2, the second common line 26, and the zone between the gate line 2 and the second common line 26). That is, the orthogonal projection of the second transistor T2 on the base substrate 1 may overlap with an orthogonal projection of the gate line 2 on the base substrate 1, with an orthogonal projection of the second common line 26 on the base substrate 1, and with an orthogonal projection of the zone between the gate line 2 and the second common line 26 on the base substrate 1.

It may be understood that in the first direction X, the first sub-pixel electrode 41 of each sub-pixel P is a sub-pixel electrode located at one side of the gate line 2, and for example, a sub-pixel electrode located at an upper side of the gate line 2; and the second sub-pixel electrode 42 of each sub-pixel is a sub-pixel electrode located at the other side of the gate line 2, and for example, a sub-pixel electrode located at a lower side of the gate line 2. In the first direction X, the main pixel portions PA of the sub-pixels P are distributed alternately. That is, in the first direction X, one of main pixel portions PA of two adjacent sub-pixels P is located at the upper side of the gate line 2, and the other one of the main pixel portions PA of two adjacent sub-pixels P is located at the lower side of the gate line 2. Similarly, in the first direction X, the auxiliary pixel portions PB of the sub-pixels P are distributed alternately. That is, in the first direction X, one of auxiliary pixel portions PB of two adjacent sub-pixels P is located at the upper side of the gate line 2, and the other one of the auxiliary pixel portions PB of the two adjacent sub-pixels P is located at the lower side of the gate line 2.

In a possible implementation, with reference to FIGS. 1A-1F, 2A-2F, 3A-3F, and 4A-4F, the third transistors T3 of the plurality of sub-pixels P are electrically connected with the first common line 25 and the second common line 26 in the sub-pixel row alternately. In this way, the main pixel portions PA and the auxiliary pixel portions PB may be arranged alternately. Specifically, the third transistor T3 may be electrically connected with the first common line 25 or the second common line 26 by a third via K3.

In a possible implementation, with reference to FIGS. 1A-1F, 2A-2F, 3A-3F, and 4A-4F, the first transistor T1 includes: a first-transistor gate electrode (which is not shown in the figure and may be specifically a reused part of the gate line 2), a first-transistor first electrode T1a, and a first-transistor second electrode T1b. The second transistor T2 includes: a second-transistor gate electrode (which is not shown in the figure and may be specifically a reused part of the gate line 2), a second-transistor first electrode T2a, and a second-transistor second electrode T2b. The third transistor T3 includes: a third-transistor gate electrode (which is not shown in the figure and may be specifically a reused part of the gate line 2), a third-transistor first electrode T3a, and a third-transistor second electrode T3b. The first-transistor second electrodes T1b and the second-transistor second electrodes T2b of the plurality of sub-pixels P are reused as the third-transistor first electrodes T3a alternately in the sub-pixel row.

In a possible implementation, with reference to FIGS. 1A-1F, 2A-2F, 3A-3F, and 4A-4F, the plurality of first-transistor second electrodes T1b include: first-type second electrodes T1bX and second-type second electrodes T1bY. The first-type second electrode T1bX includes: a first-type first part T1bX1 extending in the first direction X, a first-type second part T1bX2 extending from one end of the first-type first part T1bX1 to one side of the gate line 2, and a first-type third part T1bX3 extending from the other end of the first-type first part T1bX1 to one side of the gate line 2. The second-type second electrode T1bY includes: a second-type first part T1bY1 extending in the first direction X, and a second-type second part T1bY2 extending from one end of the second-type first part T1bY1 to one side of the gate line. The first-type second electrodes and the second-type second electrodes are distributed in the sub-pixel row alternately.

In a possible implementation, with reference to FIGS. 1A-1F, 2A-2F, 3A-3F, and 4A-4F, the second-transistor second electrodes T2b include: third-type second electrodes T2bX and fourth-type second electrodes T2bY. The third-type second electrode T2bX includes: a third-type first part T2bX1 extending in the first direction X, a third-type second part T2bX2 extending from one end of the third-type first part T2bX1 to one side of the gate line 2, and a third-type third part T2bX3 extending from the other end of the third-type first part T2bX1 to one side of the gate line 2. The fourth-type second electrode T2bY includes: a fourth-type first part T2bY1 extending in the first direction X, and a fourth-type second part T2bY2 extending from one end of the fourth-type first part T2bY1 to one side of the gate line 2. The third-type second electrodes and the fourth-type second electrodes distributed in the sub-pixel row alternately.

In a possible implementation, with reference to FIGS. 1A-1F, 2A-2F, 3A-3F, and 4A-4F, the first common line 25 is provided with a first common convex portion 25a facing one side of the gate line 2. An orthogonal projection of the third-transistor second electrode T3b on the base substrate 1 and an orthogonal projection of the first common convex portion 25a on the base substrate 1 have an overlapping region. The first common line 25 may be in connection with the third-transistor second electrode T3b at the first common convex portion 25a by a third via K3. The second common line 26 is provided with a second common convex portion 26a facing one side of the gate line 2. The orthogonal projection of the third-transistor second electrode T3b on the base substrate 1 and an orthogonal projection of the second common convex portion 26a on the substrate have an overlapping region. The second common line 26 may be in connection with another third-transistor second electrode T3b at the second common convex portion 26a by another third via K3. In the sub-pixel row, the adjacent first common convex portions 25a are spaced by one of the sub-pixels P, that is, one first common convex portion 25a may be provided between every two sub-pixels P; and the adjacent second common convex portions 26a are spaced by one of the sub-pixels, that is, one second common convex portion 26a may be provided between every two sub-pixels P. The first common convex portion 25a and the second common convex portion 26a are distributed in a staggered manner. Specifically, as shown in FIG. 1B, a first straight line k1 extending in the second direction Y and passing a center of the first common convex portion 25a does not coincide with a second straight line k2 extending in the second direction Y and passing a center of the second common convex portion 26a.

In a possible implementation, with reference to FIGS. 1F and 1H, FIG. 1H is a sectional view along the second direction at the via K3 in FIG. 1A. The array substrate may further include a lapping electrode 43. Optionally, the lapping electrode 43 may be arranged in the same layer and made of the same material as the pixel electrode. The third via K3 may be a semi-via. The third via K3 partially exposes the first common line 25 (or the second common line 26) and partially exposes the third-transistor second electrode T3b. The lapping electrode 43 is partially in contact with the first common line 25 (or the second common line 26) and is partially in contact with the third-transistor second electrode T3b at the third via K3. In this way, the first common line 25 (or the second common line 26) is electrically connected with the third-transistor second electrode T3b by the lapping electrode 43. Specifically, the third via K3 is designed as a semi-via, such that a stepped structure may be formed in the third via K3, so as to play a drainage role for alignment liquid and avoid moire phenomena in an image.

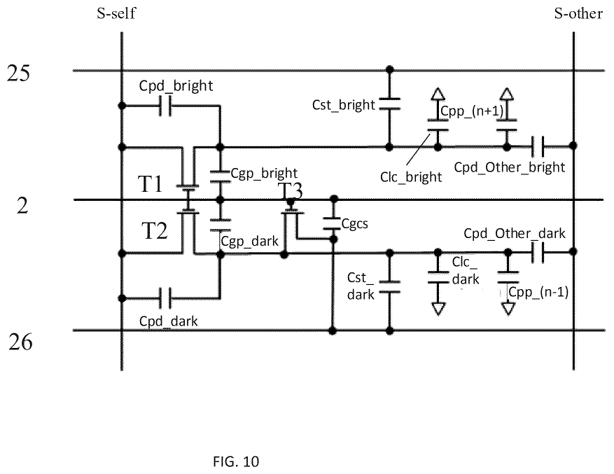

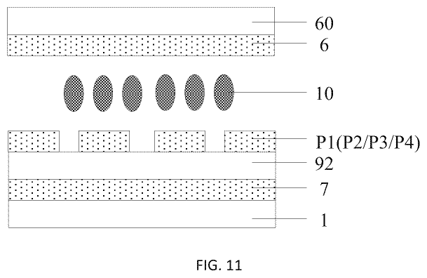

Specifically, FIG. 10 may be a diagram of an equivalent circuit at a second one of sub-pixels P from the left in FIG. 1A. S-self indicates a data line at a left side of a pixel, which is a signal line that transmits a data signal to a current sub-pixel P, that is, a data line electrically connected with the current sub-pixel P. S-other indicates a data line at a right side of a pixel, which is a data line of an adjacent pixel in a transverse direction. A pixel circuit may include: a first transistor T1, a second transistor T2, a third transistor T3, a first capacitor Cpd_bright, a second capacitor Cgp_bright, a third capacitor Cst_bright, a fourth capacitor Clc_bright, a fifth capacitor Cpp(n+1), a sixth capacitor Cpd_other_bright, a seventh capacitor Cpd_dark, an eighth capacitor Cgp_dark, a ninth capacitor Cst_dark, a tenth capacitor Clc_dark, an eleventh capacitor Cpp(n−1), a twelfth capacitor Cpd_other_dark, and a thirteenth capacitor Cgcs. The first capacitor Cpd_bright is formed between the first sub-pixel electrode 41 and the data line 3. The second capacitor Cgp_bright is formed between the first sub-pixel electrode 41 and the gate line 2. The third capacitor Cst_bright may be formed in the overlapping region of the first sub-pixel electrode 41 and the first common line 25. The fourth capacitor Clc_bright may be formed between the first sub-pixel electrode 41 and a common electrode on an opposing substrate. The fifth capacitor Cpp(n+1) may be formed between a first sub-pixel electrode 41 of a current sub-pixel P and a second sub-pixel electrode 42 of a previous sub-pixel P. The sixth capacitor Cpd_other_bright may be formed between the first sub-pixel electrode 41 and the adjacent data line 3. The seventh capacitor Cpd_dark is formed between the second sub-pixel electrode 42 and the data line 3. The eighth capacitor Cgp_dark is formed between the second sub-pixel electrode 42 and the gate line 2. The ninth capacitor Cst_dark may be formed in the overlapping region of the second sub-pixel electrode 42 and the second common line 26. The tenth capacitor Clc_dark may be formed between the second sub-pixel electrode 42 and the common electrode on the opposing substrate. The eleventh capacitor Cpp(n−1) may be formed between a second sub-pixel electrode 42 of a current sub-pixel P and a first sub-pixel electrode 41 of a next sub-pixel P. The twelfth capacitor Cpd_other_dark may be formed between the second sub-pixel electrode 42 and the adjacent data line 3. The thirteenth capacitor Cgcs may be formed in the overlapping region of the gate line 2 and the third-transistor second electrode T3b. Specifically, as shown in FIGS. 1A and 11, because the third transistor T3 is connected with the second transistor T2, a voltage loaded on the second sub-pixel electrode 42 may be partially transmitted to the thirteenth capacitor Cgcs by the third transistor T3 and/or the common line for transmission (the first common line 25 or the second common line 26), such that a voltage obtained by the second sub-pixel electrode 42 is smaller than that obtained by the first sub-pixel electrode 41, further brightness of the second sub-pixel electrode 42 is smaller than that of the first sub-pixel electrode 41. The second sub-pixel electrode 42 is used as the auxiliary pixel portion PB, and the first sub-pixel electrode 41 is used as the main pixel portion PA. For an adjacent sub-pixel P (a first one of sub-pixels P from the left in FIG. 1A), because the third transistor T3 is connected with the first transistor T1, a voltage loaded on the first sub-pixel electrode 41 may be partially transmitted to the fourteenth capacitor (not shown in FIG. 11) between the gate line 2 and the third-transistor second electrode T3b via the third transistor T3, such that a voltage obtained by the first sub-pixel electrode 41 is smaller than that obtained by the second sub-pixel electrode 42, further brightness of the first sub-pixel electrode 41 is smaller than that of the second sub-pixel electrode 42. The first sub-pixel electrode 41 is used as the auxiliary pixel portion PB, and the second sub-pixel electrode 42 is used as the main pixel portion PA. In this way, a bright-dark alternate distribution effect is achieved in the sub-pixel row.

In a possible implementation, with reference to FIGS. 1A-1F, 2A-2F, 3A-3F, and 4A-4F, the array substrate may further include a third common line 27 that electrically connects the first common line 25 and the second common line 26. An orthogonal projection of the third common line 27 on the base substrate 1 is located at two sides of the orthogonal projection of the data line 3 on the base substrate 1. Coupling capacitance between the data line 3 and the first sub-pixel electrode 41 (or the second sub-pixel electrode 42) can be improved.

In a possible implementation, with reference to FIGS. 1A-1F, 2A-2F, 3A-3F, and 4A-4F, the first sub-pixel electrode 41 is of an integrated structure, and the second sub-pixel electrode 42 is of an integrated structure.

In a possible implementation, with reference to FIGS. 1F, 2F, 3F, and 5A-5F, the first sub-pixel electrode 41 includes: a first electrode part P1 and a second electrode part P2 that are sequentially distributed in the second direction Y. The second sub-pixel electrode 42 includes: a third electrode part P3 and a fourth electrode part P4 that are sequentially distributed in the second direction Y. The first electrode part P1 is provided with a plurality of first slits F1, the second electrode part P2 is provided with a plurality of second slits F2, the third electrode part P3 is provided with a plurality of third slits F3, and the fourth electrode part P4 is provided with a plurality of fourth slits F4. In a possible implementation, with reference to FIGS. 1F, 2F and 3F, an extending direction of the first slits F1 is the same as that of the second slits F2, an extending direction of the third slits F3 is the same as that of the fourth slits F4, and the extending direction of the first slits F1 is different from that of the third slits F3. In a possible implementation, as shown in FIG. 5F, the extending direction of the first slits F1 is the same as that of the fourth slits F4, the extending direction of the second slits F2 is the same as that of the third slits F3, and the extending direction of the first slits F1 is different from that of the second slits F2.

Specifically, with reference to FIGS. 1F, 2F and 3F, an included angle formed by the extending direction of the first slit F1 and the first direction X may be 40°-50°, and for example, may be 45°. An included angle formed by the extending direction of the second slit F2 and the first direction X may be 40°-50°, and for example, may be 45°. An included angle formed by the extending direction of the third slit F3 and the first direction X may be 130°-140°, and for example, may be 135°. An included angle formed by the extending direction of the fourth slit F4 and the first direction X may be 130°-140°, and for example, may be 135°.

Specifically, with reference to FIG. 5F, an included angle formed by the extending direction of the first slit F1 and the first direction X may be 40°-50°, and for example, may be 45°. An included angle formed by the extending direction of the second slit F2 and the first direction X may be 130°-140°, and for example, may be 135°. An included angle formed by the extending direction of the third slit F3 and the first direction X may be 130°-140°, and for example, may be 135°. An included angle formed by the extending direction of the fourth slit F4 and the first direction X may be 40°-50°, and for example, may be 45°.

In a possible implementation, with reference to FIGS. 1F and 2F, fifth slits F5 are further provided between the first electrode part P1 and the second electrode part P2, and an extending direction of the fifth slits F5 is different from that of the first slits F1. Sixth slits F6 are further provided between the third electrode part P3 and the fourth electrode part P4, and an extending direction of the sixth slits F6 is different from that of the third slits F3. In the embodiments of the disclosure, the fifth slits F5 are provided between the first electrode part P1 and the second electrode part P2, which can reduce transverse dark lines in a center of the first sub-pixel electrode 41. The sixth slits F6 are provided between the third electrode part P3 and the fourth electrode part P4, which can reduce transverse dark lines in a center of the second sub-pixel electrode 42. In this way, an aperture ratio of a display panel can be further improved.

In a possible implementation, with reference to FIG. 1F, the fifth slit F5 extends in the second direction Y, and the sixth slit F6 extends in the second direction Y.

In a possible implementation, with reference to FIG. 2F, the extending direction of the fifth slit F5 is the same as that of the third slit F3, and the extending direction of the sixth slit F6 is the same as that of the first slit F1.

In a possible implementation, with reference to FIG. 3F, one side of the first electrode part P1 facing the second electrode part P2 is semi-closed, and one side of the second electrode part P2 facing the first electrode part P1 is semi-closed. A closed position of the first electrode part P1 facing the second electrode part P2 is opposite to an open position of the second electrode part P2 facing the first electrode part P1. An open position of the first electrode part P1 facing the second electrode part P2 is opposite to a closed position of the second electrode part P2 facing the first electrode part P1. The closed position of the second electrode part P2 facing the first electrode part P1 is connected with the closed position of the first electrode part P1 facing the second electrode part P2, and the connection position is located in a middle zone of the first electrode part P1 (or the second electrode part P2) in the first direction X.

In a possible implementation, with reference to FIGS. 4A-4F, the first slit F1 of the first electrode part P1 and the second slit F2 of the second electrode part P2 are of an integrated structure. The third slit F3 of the third electrode part P3 and the fourth slit F4 of the fourth electrode part P4 are of an integrated structure.

In a possible implementation, with reference to FIGS. 5A-5F, the array substrate includes: a gate line 2 extending in the first direction X, a data line 3 extending in the second direction Y, a first common line 25 distributed at one side of the gate line 2, and a second common line 26 distributed at the other side of the gate line 2. The sub-pixel P includes: a first transistor T1, a second transistor T2, a third transistor T3 electrically connected with one of the first transistor T1 and the second transistor T2, and a first electrode part P1, a second electrode part P2, a third electrode part P3 and a fourth electrode part P4 that are sequentially distributed in the second direction Y. The first electrode part P1 is electrically connected with one of the third electrode part P3 and the fourth electrode part P4, such that a first connection sub-pixel electrode P11 is formed. For example, as shown in FIG. 5A, the first electrode part P1 and the fourth electrode part P4 are electrically connected to form the first connection sub-pixel electrode P11. The second electrode part P2 is electrically connected with the other of the third electrode part P3 and the fourth electrode part P4, such that a second connection sub-pixel electrode P12 is formed. For example, as shown in FIG. 5A, the second electrode part P2 and the third electrode part P3 are electrically connected to form the second connection sub-pixel electrode P12. In the sub-pixel row, the first connection sub-pixel electrodes P11 of the plurality of sub-pixels P are electrically connected with the first transistors T1 and the second transistors T2 alternately; and the second connection sub-pixel electrodes P12 of the plurality of sub-pixels P are electrically connected with the first transistors T1 and the second transistors T2 alternately. In the same sub-pixel, the first connection sub-pixel electrode P11 and the second connection sub-pixel electrode P12 are electrically connected with different transistors.

In the embodiments of the disclosure, a connection position of the third transistor T3 is fixed. A connection relation between the first connection sub-pixel electrode P11 and the first transistor T1 as well as the second transistor T2 and a connection relation between the second connection sub-pixel electrode P12 and the first transistor T1 as well as the second transistor T2 are adjusted, such that the first connection sub-pixel electrode P11 may be used as the main pixel portion PA or the auxiliary pixel portion PB, and the second connection sub-pixel electrode P12 may be used as the main pixel portion PA or the auxiliary pixel portion PB. The first connection sub-pixel electrodes P11 may be electrically connected with the first transistors T1 and the second transistors T2 alternately, and the second connection sub-pixel electrodes P12 of the plurality of sub-pixels P may be electrically connected with the first transistors T1 and the second transistors T2 alternately. The main pixel portions PA and the auxiliary pixel portions PB may be arranged alternately, and further an effect of improving transmittance and avoiding color cast can be achieved.

Specifically, an orthogonal projection of the first transistor T1 on the base substrate 1 may be distributed in the first zone S1 (the first zone S1 may include: the gate line 2, the first common line 25, and the zone between the gate line 2 and the first common line 25). That is, the orthogonal projection of the first transistor T1 on the base substrate 1 may overlap with an orthogonal projection of the gate line 2 on the base substrate 1, with an orthogonal projection of the first common line 25 on the base substrate 1, and with an orthogonal projection of the zone between the gate line 2 and the first common line 25 on the base substrate 1. An orthogonal projection of the second transistor T2 on the base substrate 1 may be distributed in the second zone S2 (the second zone S2 may include: the gate line 2, the second common line 26, and the zone between the gate line 2 and the second common line 26). That is, the orthogonal projection of the first transistor T1 on the base substrate 1 may overlap with the orthogonal projection of the gate line 2 on the base substrate 1, with an orthogonal projection of the second common line 26 on the base substrate 1, and with an orthogonal projection of the zone between the gate line 2 and the second common line 26 on the base substrate 1.

Specifically, in the sub-pixel row, the third transistor T3 may be only electrically connected with the second transistor T2, as shown in FIG. 5A. In another possible implementation, the third transistor T3 may be only electrically connected with the first transistor T1.

In a possible implementation, with reference to FIGS. 5A-5F, the first electrode part P1 is electrically connected with the fourth electrode part P4, and the second electrode part P2 is electrically connected with the third electrode part P3. In another possible implementation, with reference to FIGS. 6A-6F, the first electrode part P1 is electrically connected with the third electrode part P3, and the second electrode part P2 is electrically connected with the fourth electrode part P4.

In a possible implementation, with reference to FIGS. 5A-5F, the array substrate further includes: first connecting parts P5 and second connecting parts P6 that extend in the second direction Y. One end of the first connecting part P5 is electrically connected with the first electrode part P1, and the other end of the first connecting part is electrically connected with the fourth electrode part P4. One end of the second connecting part P6 is electrically connected with the second electrode part P2, and the other end of the second connecting part is electrically connected with the third electrode part P3. In this way, the first electrode part P1 is electrically connected with the fourth electrode part P4, and the second electrode part P2 is electrically connected with the third electrode part P3.

Specifically, as shown in FIGS. 5A-5F, the first connecting part P5 extends in the second direction Y, and an orthogonal projection of the first connecting part on the base substrate 1 is located at one side of the second electrode part P2 and the third electrode part P3. The second connecting part P6 extends in the second direction Y, and an orthogonal projection of the second connecting part on the base substrate 1 is located in a zone between the first common line 25 and the second common line 26.

In a possible implementation, with reference to FIGS. 5A-5F, the array substrate further includes: first connecting convex portions P7 connected with the first connecting parts P5 and protruding toward one side of the third transistors T3.

In the sub-pixel row, the first connecting convex portions P7 are electrically connected with the first transistors T1 and the second transistors T2 alternately. In this way, the first connection sub-pixel electrodes P11 and the second connection sub-pixel electrodes P12 may be electrically connected with the first transistors T1 and the second transistors T2 alternately.

In a possible implementation, with reference to FIGS. 5A-5F, extending lines in the first direction X of outer edges of first connecting convex portions P7 adjacent in the sub-pixel row do not coincide with each other.

In a possible implementation, with reference to FIGS. 6A-6F, the first electrode part P1 is electrically connected with the third electrode part P3, such that the first connection sub-pixel electrode P11 is formed. The second electrode part P2 is electrically connected with the fourth electrode part P4, such that the second connection sub-pixel electrode P12 is formed.

In a possible implementation, with reference to FIGS. 6A-6F, the array substrate further includes: third connecting parts P8 and fourth connecting parts P9 that extend in the second direction Y. One end of the third connecting part P8 is electrically connected with the first electrode part P1, and the other end of the third connecting part is electrically connected with one side of the third electrode part P3 facing the second electrode part P2. One end of the fourth connecting part P9 is electrically connected with the second electrode part P2, and the other end of the fourth connecting part is electrically connected with the fourth electrode part P4. Optionally, with reference to FIGS. 6A, 6D and 6F, orthogonal projections of the fourth connecting part P9 and the second-transistor second electrode T2b on the base substrate 1 have an overlapping region. The orthogonal projection of the fourth connecting part P9 on the base substrate 1 at least partially overlaps with an orthogonal projection of the third common line 27 on the base substrate 1. An orthogonal projection of the third connecting part P8 on the base substrate 1 and the orthogonal projection of the third common line 27 on the base substrate 1 have an overlapping region.

In a possible implementation, with reference to FIGS. 6A, 6D and 6F, in a sub-pixel P (for example, in a left one of sub-pixels P in FIG. 6F), one end of the third connecting part P8 is electrically connected with one end of the first electrode part P1 facing the second electrode part P2, and is electrically connected with one end of the third electrode part P3 facing the second electrode part P2 after bypassing one side of the second electrode part P2.

That is, the third connecting part P8 is arranged on a right edge of the sub-pixel P. In another adjacent sub-pixel P (for example, in a middle one of sub-pixels P in FIG. 6F), one end of the third connecting part P8 is electrically connected with one end of the first electrode part P1 facing the second electrode part P2, and is electrically connected with the third electrode part P3 after passing the zone between the first transistor T1 and the third transistor T3 and bypassing one side of the second electrode part P2. That is, the third connecting part P8 is arranged on a left edge of the sub-pixel P.

In a possible implementation, with reference to FIGS. 6A, 6D and 6F, in a sub-pixel P (for example, in a left one of sub-pixels P in FIG. 6F), one end of the fourth connecting part P9 is electrically connected with one end of the second electrode part P2 facing the third electrode part P3, and is electrically connected with the fourth electrode part P4 after passing the zone between the first transistor T1 and the third transistor T3 and bypassing one side of the third electrode part P3. That is, the fourth connecting part P9 is arranged on a left edge of the sub-pixel P. In another adjacent sub-pixel P (for example, in a middle one of sub-pixels P in FIG. 6F), one end of the fourth connecting part P9 is electrically connected with one end of the second electrode part P2 facing the third electrode part P3, and is electrically connected with one end of the fourth electrode part P4 facing the third electrode part P3 after bypassing one side of the third electrode part P3. That is, the fourth connecting part P9 is arranged on a right edge of the sub-pixel P.

Specifically, as shown in FIGS. 6A-6F, the third connecting part P8 extends in the second direction Y, and the orthogonal projection of the third connecting part on the base substrate 1 is located at one side of the second electrode part P2. The orthogonal projection of the fourth connecting part P9 on the base substrate 1 is located partially in the zone between the first common line 25 and the second common line 26, and partially at one side of the third electrode part P3.

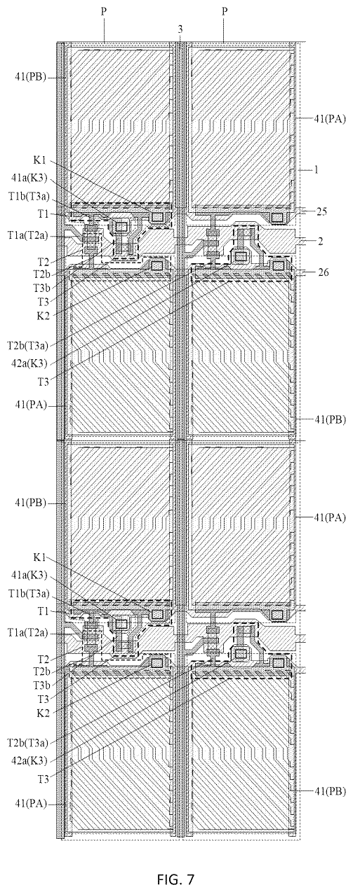

In a possible implementation, with reference to FIG. 7, the plurality of sub-pixels include: sub-pixel columns extending in the second direction Y and arranged in the first direction X. The main pixel portions PA and the auxiliary pixel portions PB are arranged in the sub-pixel column alternately. In the embodiments of the disclosure, the main pixel portions PA and the auxiliary pixel portions PB are arranged in the sub-pixel column alternately. Two sub-pixels in the first direction X may achieve a 2P8D effect of bright-dark compensation, and meanwhile, two sub-pixels in the second direction Y may achieve an effect of bright-dark compensation, such that an effect of both improving transmittance and avoiding color cast can be achieved.

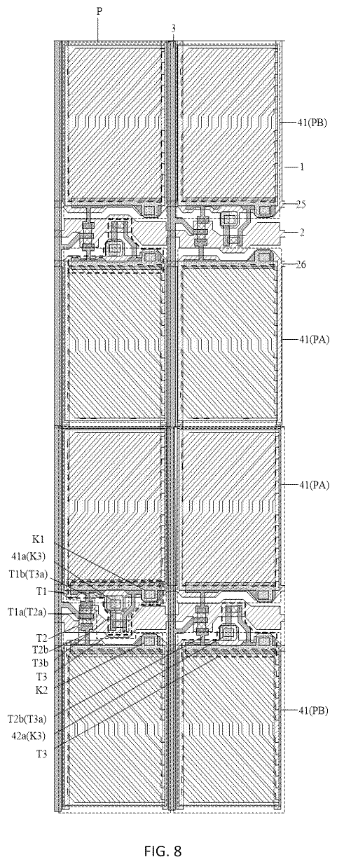

In a possible implementation, with reference to FIG. 8, the plurality of sub-pixels include: sub-pixel columns extending in the second direction Y and arranged in the first direction. Two main pixel portions PA and two auxiliary pixel portions PB are arranged in the sub-pixel column alternately. In the embodiments of the disclosure, two main pixel portions PA and two auxiliary pixel portions PB are arranged in the sub-pixel column alternately. Two sub-pixels in the first direction X may achieve a 2P8D effect of bright-dark compensation, and meanwhile, two sub-pixels in the second direction Y may achieve an effect of bright-dark compensation, such that an effect of both improving transmittance and avoiding color cast can be achieved.

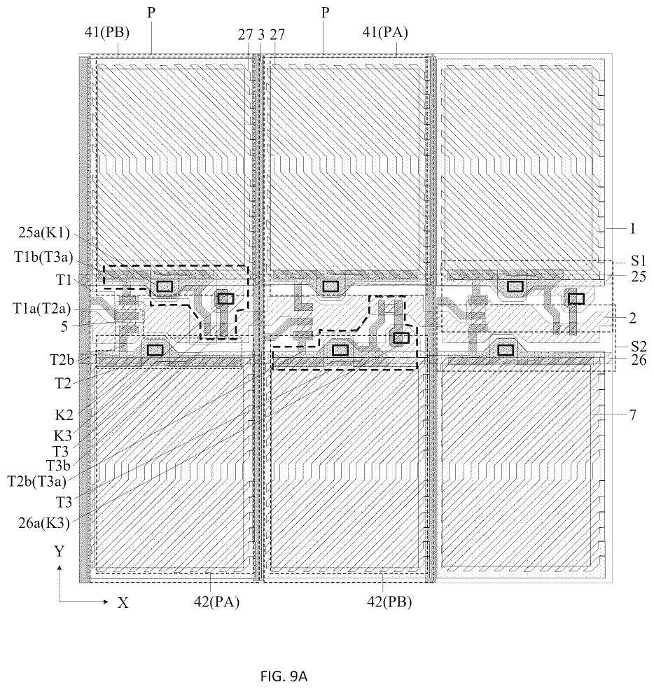

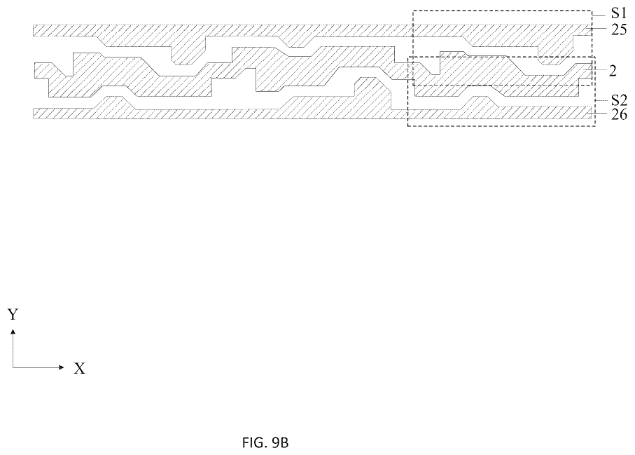

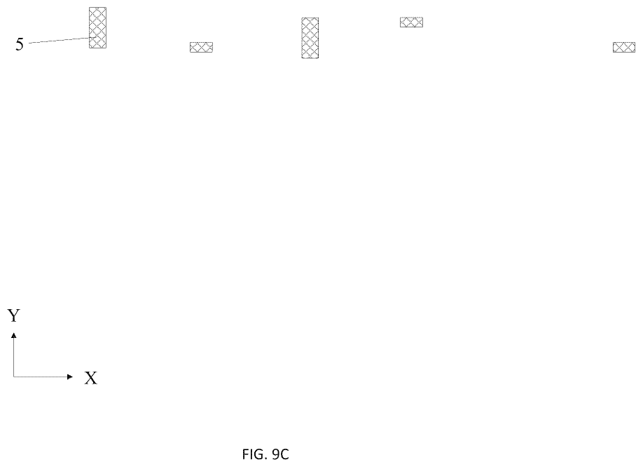

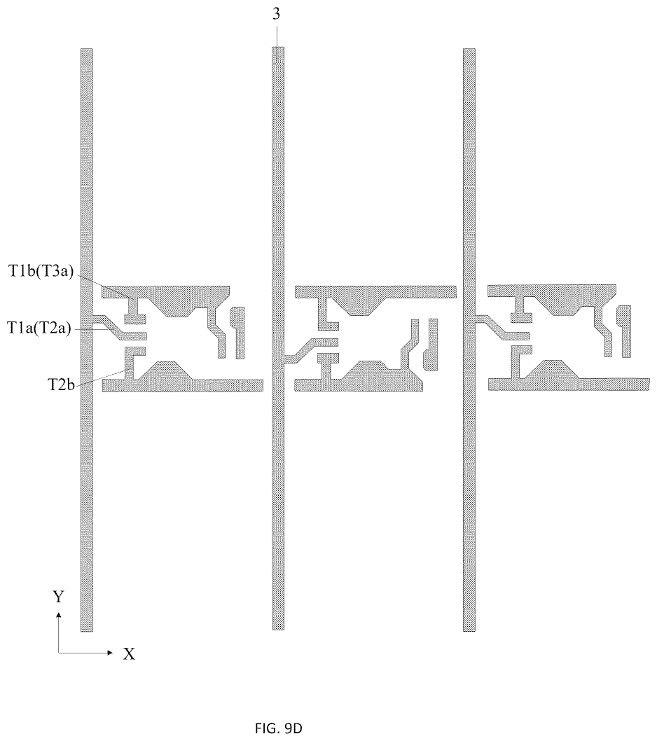

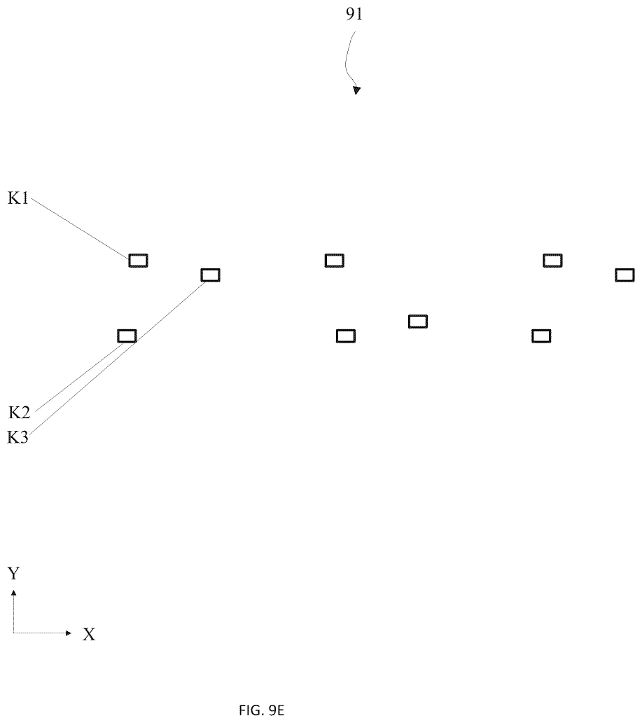

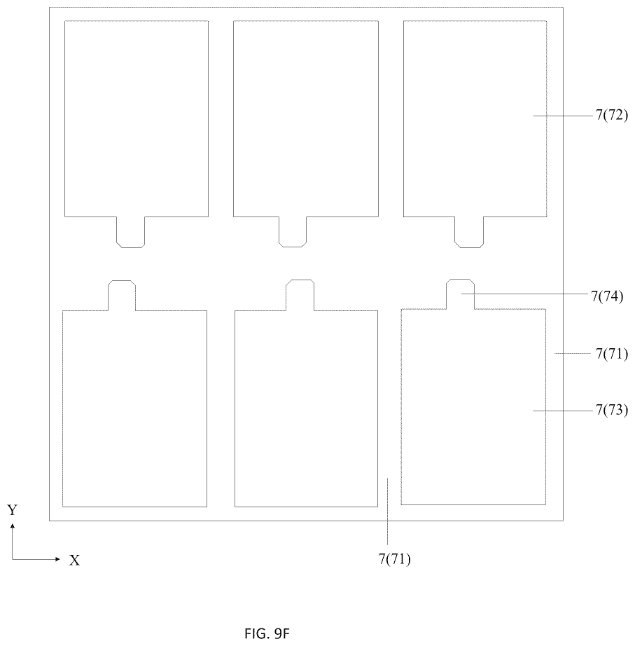

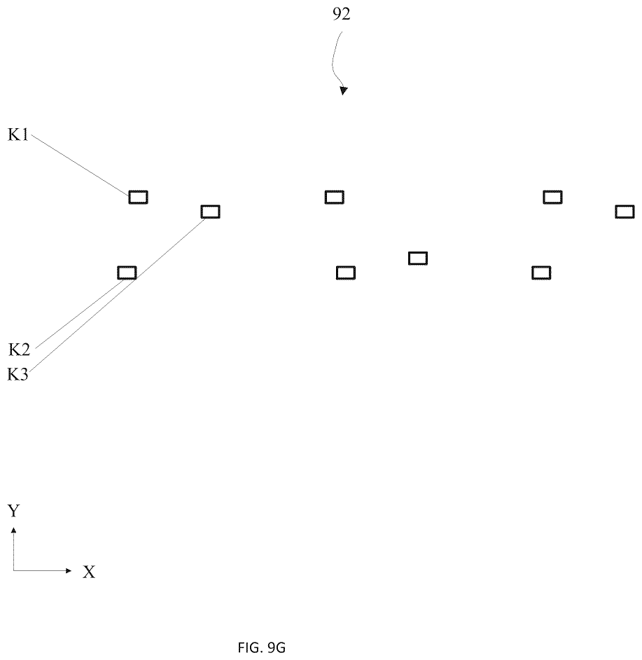

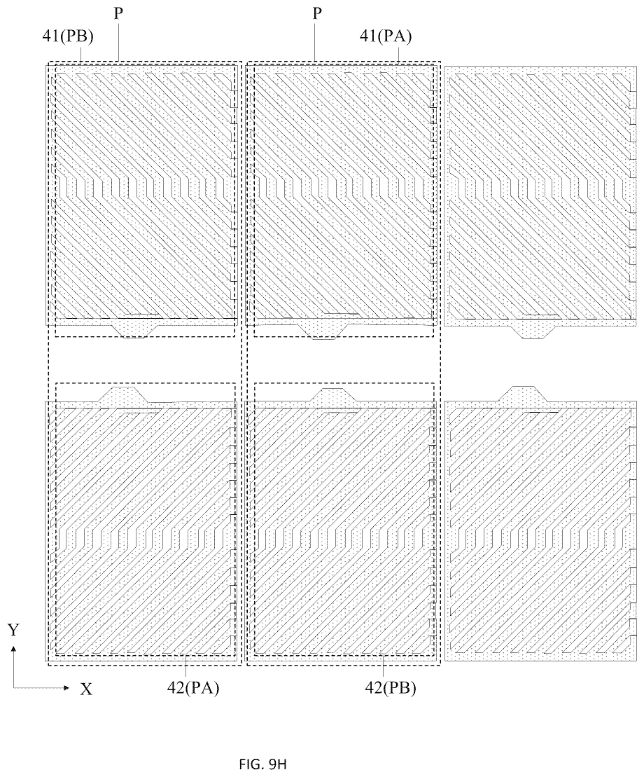

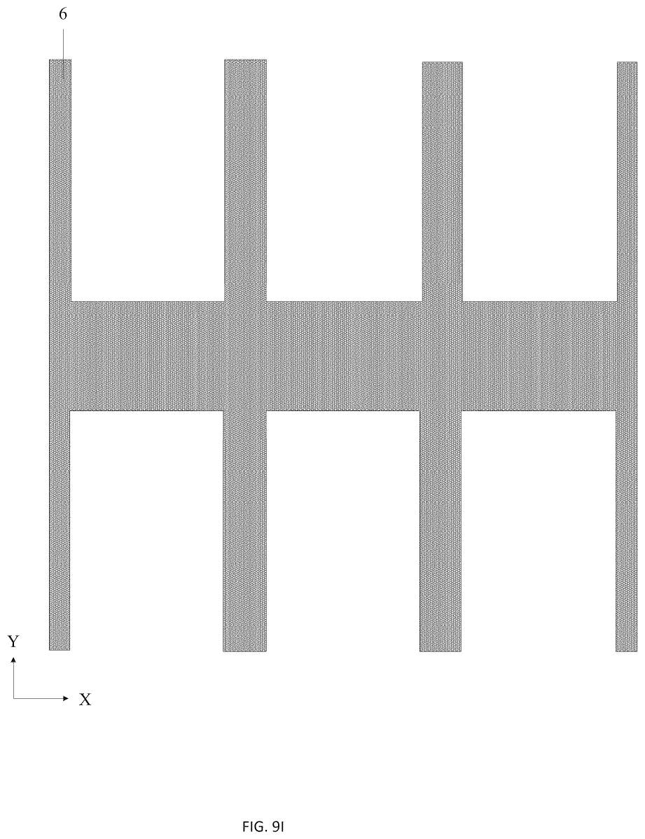

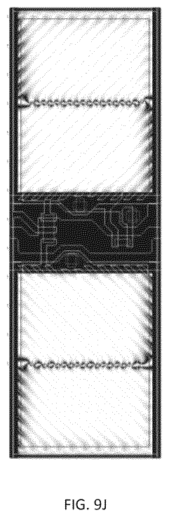

In a possible implementation, with reference to FIGS. 9A-9H, the array substrate further includes: a first electrode layer 7. The first electrode layer 7 includes: a first electrode connecting part 71, a first hollowed-out structure 72, and a second hollowed-out structure 73. An orthogonal projection of the first hollowed-out structure 72 on the base substrate 1 at least partially overlaps with an orthogonal projection of the first sub-pixel electrode 41 on the base substrate 1. An orthogonal projection of the second hollowed-out structure 73 on the base substrate 1 at least partially overlaps with an orthogonal projection of the second sub-pixel electrode 42 on the base substrate 1. In the embodiments of the disclosure, for a vertical alignment (VA) display panel in which an array substrate is provided with a pixel electrode layer and an opposing substrate is provided with a common electrode layer, positions having the first hollowed-out structure 72 and the second hollowed-out structure 73 has different pressure differences from those having no first hollowed-out structure 72 and no second hollowed-out structure 73 in the same pixel electrode, such that liquid crystal can be twisted more evenly, dark lines corresponding to the pixel electrode can be reduced, a width of a black matrix can be reduced, and transmittance of the display panel can be improved. Moreover, in the array substrate, in addition to a vertical electric field formed by the pixel electrode and the common electrode, the pixel electrode and the first electrode layer 7 may form a transverse electric field, such that deflection orientations of the liquid crystal can be increased, and a color cast problem of the display panel can be solved.

In a possible implementation, as shown in FIGS. 9A-9H, the first electrode layer 7 further includes: a third hollowed-out structure 74, such that the first sub-pixel electrode 41 (or the second sub-pixel electrode 42, or the first electrode part P1, or the second electrode part P2, or the third electrode part P3, or the fourth electrode part P4) above the first electrode layer 7 may be in connection with the first-transistor second electrode T1b or the second-transistor second electrode T2b below the first electrode layer 7 at the third hollowed-out structure 74.

Specifically, the first electrode layer 7 may be located between the base substrate 1 and the pixel electrode layer. Specifically, the first electrode layer 7 and the common electrode layer of the opposing substrate may be provided with the same signal. The first electrode layer 7 may be a transparent electrode layer. The first electrode layer 7 may be made of indium tin oxide.

In a possible implementation, with reference to FIGS. 9A-9G, an orthogonal projection of the first electrode connecting part 71 on the base substrate 1 covers an orthogonal projection of the data line 3 on the base substrate 1. In the embodiments of the disclosure, the orthogonal projection of the first electrode connecting part 71 on the base substrate 1 covers the orthogonal projection of the data line 3 on the base substrate 1, such that coupling capacitance between the pixel electrode and the data line 3 can be shielded by the first electrode connecting part 71, the third common line 27 can be omitted, and further transmittance of the display panel can be improved.

In a possible implementation, the first electrode layer 7 may be arranged in the array substrate shown in FIGS. 5A and 6A, the orthogonal projection of the first hollowed-out structure 72 of the first electrode layer 7 on the base substrate 1 may overlap with the orthogonal projections of the first electrode part P1 and the second electrode part P2 on the base substrate 1, and the orthogonal projection of the second hollowed-out structure 73 of the first electrode layer 7 on the base substrate 1 may overlap with the orthogonal projections of the third electrode part P3 and the fourth electrode part P4 on the base substrate 1.

With reference to FIGS. 1G, 2G, 3G, 4G, 5G and 9J, the embodiments of the disclosure conducts optical simulation on different array substrate structures. Through comparison of transverse dark lines in centers of sub-pixels, it may be determined that in the array substrate structures without the first electrode layer 7 corresponding to FIGS. 1G, 2G, 3G, 4G and 5G, transmittance of the structure corresponding to FIG. 1A is the greatest, a simulation value of which may be 6.34%; and the corresponding array substrate structure with the first electrode layer 7 as shown in FIG. 9J has greater transmittance, a simulation value of which may be 6.95%.

Based on the same inventive conception, embodiments of the disclosure further provide a display panel. As shown in FIG. 11, the display panel includes the array substrate according to the embodiments of the disclosure, and further includes an opposing substrate arranged opposite to the array substrate. One side of the opposing substrate facing the array substrate is provided with a common electrode layer 8.

Specifically, the first common line 25, the second common line 26, the third common line 27, the first electrode layer 7, and the common electrode layer 8 of the opposing substrate may be provided with the same signal.

In a possible implementation, as shown in FIGS. 9A-9G and 11, the data line 3 may be located at one side of the gate line 2 facing away from the base substrate 1. The first electrode layer 7 may be located at one side of the data line 3 facing away from the gate line 2. The pixel electrode (including the first electrode part P1, the second electrode part P2, the third electrode part P3, and the fourth electrode part P4) may be located at one side of the first electrode layer 7 facing away from the data line 3. A gate insulation layer may be arranged between a layer where the gate line 2 is located and a layer where the data line 3 is located. An active layer may be arranged between the gate insulation layer and the data line 3 (the active layer may include an active pattern 5, and the active layer may be made of amorphous silicon, low-temperature polysilicon, metal oxide and other materials, which is not limited herein). A first insulation layer 91 may be arranged between the data line 3 and the first electrode layer 7. A second insulation layer 92 may be arranged between the first electrode layer 7 and the pixel electrode.

In a possible implementation, as shown in FIGS. 9A-9I and 11, the display panel may be further provided with a black matrix 6. An orthogonal projection of the black matrix 6 on the base substrate 1 may cover the orthogonal projection of the gate line 2 on the base substrate 1 and the orthogonal projection of the data line 3 on the base substrate 1. Specifically, the opposing substrate may include an opposing base 80, and the black matrix 6 may be located between the opposing base 80 and the common electrode layer 8 (not shown in FIG. 11).

In a possible implementation, with reference to FIG. 11, the first electrode layer 7 is located at one side of the pixel electrode (including the first electrode part P1, the second electrode part P2, the third electrode part P3, and the fourth electrode part P4) away from the opposing substrate. In the embodiments of the disclosure, the first electrode layer 7 is located at the side of the pixel electrode away from the opposing substrate, such that first overlapping capacitance between the pixel electrode and the gate line 2 and second overlapping capacitance between the pixel electrode and the data line 3 can be blocked (or shielded), and a risk of crosstalk can be greatly reduced. Meanwhile, due to existence of the first electrode layer 7, a distance between the pixel electrodes may be reduced, such that the pixel electrode may overlap with the gate line 2 and the data line 3, and a risk of light leakage of liquid crystal can be reduced. In this way, a width of the black matrix can be reduced, a pixel aperture ratio can be increased, and pixel transmittance can be improved.

Based on the same inventive conception, embodiments of the disclosure further provide a display apparatus. The display apparatus includes the display panel according to the embodiments of the disclosure. Reference may be made to the embodiment of the display panel for implementation of the display apparatus, which will not be repeated herein.

During specific implementation, in the embodiments of the disclosure, the display apparatus may be any product or component having a display function, such as a mobile phone, a tablet computer, a television, a display screen, a notebook computer, a digital photo frame, and a navigator. Other essential components of the display apparatus should be understood by those of ordinary skill in the art, which are not repeated herein and should not limit the disclosure.

Although preferred embodiments of the disclosure have been described, those skilled in the art can still make additional changes and modifications to the embodiments once they learn the basic inventive concept. Therefore, the appended claims are intended to be interpreted as including the preferred embodiments and all changes and modifications falling within the scope of the disclosure.

Apparently, those skilled in the art may make various modifications and variations to the embodiments of the disclosure without departing from the spirit and scope of the embodiments of the disclosure. In this way, if the modifications and variations of the embodiments of the disclosure fall within the scope of the claims of the disclosure and their equivalent technologies, the disclosure is also intended to involve the modifications and variations.

1-28. (canceled)

29. An array substrate, comprising:
a base substrate; and
a plurality of sub-pixels located at a side of the base substrate;
wherein the plurality of sub-pixels comprise: sub-pixel rows extending in a first direction and arranged in a second direction; and
at least one of the plurality of sub-pixels comprises: a main pixel portion and an auxiliary pixel portion distributed in the second direction, wherein brightness of the main pixel portion is greater than brightness of the auxiliary pixel portion, and the main pixel portion and the auxiliary pixel portion are arranged in the sub-pixel row alternately.

30. The array substrate according to claim 29, further comprising: a gate line extending in the first direction, a data line extending in the second direction, a first common line distributed at one side of the gate line and extending in the first direction, and a second common line distributed at the other side of the gate line and extending in the first direction;
wherein the sub-pixel comprises: a first sub-pixel electrode, a second sub-pixel electrode, a first transistor electrically connected with the first sub-pixel electrode, a second transistor electrically connected with the second sub-pixel electrode, and a third transistor electrically connected with one of the first transistor and the second transistor;
wherein the first sub-pixel electrode and the first common line are located at a same side of the gate line, and the second sub-pixel electrode and the second common line are located at a same side of the gate line; and
orthogonal projections of the third transistors of the plurality of sub-pixels on the base substrate are distributed in a first zone and a second zone in the sub-pixel row alternately, wherein the first zone comprises: the gate line, the first common line, and a zone between the gate line and the first common line; and the second zone comprises: the gate line, the second common line, and a zone between the gate line and the second common line.

31. The array substrate according to claim 29, wherein the third transistors of the plurality of sub-pixels are electrically connected with the first common line and the second common line alternately in the sub-pixel row.

32. The array substrate according to claim 29, wherein
the first transistor comprises: a first-transistor gate electrode, a first-transistor first electrode, and a first-transistor second electrode;
the second transistor comprises: a second-transistor gate electrode, a second-transistor first electrode, and a second-transistor second electrode; and
the third transistor comprises: a third-transistor gate electrode, a third-transistor first electrode, and a third-transistor second electrode;
wherein the first-transistor second electrodes and the second-transistor second electrodes of the plurality of sub-pixels are reused alternately as the third-transistor first electrodes in the sub-pixel row.

33. The array substrate according to claim 32, wherein the plurality of first-transistor second electrodes comprise: first-type second electrodes and second-type second electrodes;
wherein the first-type second electrode comprises: a first-type first part extending in the first direction, a first-type second part extending from one end of the first-type first part to a side of the gate line, and a first-type third part extending from the other end of the first-type first part to the side of the gate line;
the second-type second electrode comprises: a second-type first part extending in the first direction, and a second-type second part extending from one end of the second-type first part to the side of the gate line; and
the first-type second electrodes and the second-type second electrodes are distributed alternately in the sub-pixel row.

34. The array substrate according to claim 32, wherein the second-transistor second electrodes comprise: third-type second electrodes and fourth-type second electrodes;
wherein the third-type second electrode comprises: a third-type first part extending in the first direction, a third-type second part extending from one end of the third-type first part to a side of the gate line, and a third-type third part extending from the other end of the third-type first part to the side of the gate line;
the fourth-type second electrode comprises: a fourth-type first part extending in the first direction, and a fourth-type second part extending from one end of the fourth-type first part to the side of the gate line; and
the third-type second electrodes and the fourth-type second electrodes are distributed alternately in the sub-pixel row.

35. The array substrate according to claim 32, wherein the first common line is provided with a first common convex portion facing the side of the gate line, and an orthogonal projection of the third-transistor second electrode on the base substrate and an orthogonal projection of the first common convex portion on the base substrate have an overlapping region;
the second common line is provided with a second common convex portion facing the side of the gate line, and the orthogonal projection of the third-transistor second electrode on the base substrate and an orthogonal projection of the second common convex portion on the base substrate have an overlapping region; and
in the sub-pixel row, adjacent first common convex portions are spaced by one of the sub-pixels, adjacent second common convex portions are spaced by one of the sub-pixels, and the first common convex portion and the second common convex portion are distributed in a staggered manner.

36. The array substrate according to claim 30, wherein the first sub-pixel electrode is of an integrated structure, and the second sub-pixel electrode is of an integrated structure.

37. The array substrate according to claim 36, wherein the first sub-pixel electrode comprises: a first electrode part and a second electrode part sequentially distributed in the second direction; the second sub-pixel electrode comprises: a third electrode part and a fourth electrode part sequentially distributed in the second direction;
the first electrode part is provided with a plurality of first slits, the second electrode part is provided with a plurality of second slits, the third electrode part is provided with a plurality of third slits, and the fourth electrode part is provided with a plurality of fourth slits;
wherein an extending direction of the first slit is same as an extending direction of the second slit, an extending direction of the third slit is same as an extending direction of the fourth slit, and the extending direction of the first slit is different from the extending direction of the third slit.

38. The array substrate according to claim 37, wherein fifth slits are further provided between the first electrode part and the second electrode part, and an extending direction of the fifth slit is different from the extending direction of the first slit; and
sixth slits are further provided between the third electrode part and the fourth electrode part, and an extending direction of the sixth slit is different from the extending direction of the third slit.

39. The array substrate according to claim 38, wherein the fifth slit extends in the second direction, and the sixth slit extends in the second direction; or the extending direction of the fifth slit is same as the extending direction of the third slit, and the extending direction of the sixth slit is same as the extending direction of the first slit.

40. The array substrate according to claim 37, wherein a side of the first electrode part facing the second electrode part is of a semi-closed structure, and a side of the second electrode part facing the first electrode part is of a semi-closed structure;
a closed position of the first electrode part facing the second electrode part is opposite to an open position of the second electrode part facing the first electrode part; and
an open position of the first electrode part facing the second electrode part is opposite to a closed position of the second electrode part facing the first electrode part.

41. The array substrate according to claim 37, wherein the first slit of the first electrode part is integrated with the second slit of the second electrode part; and
the third slit of the third electrode part is integrated with the fourth slit of the fourth electrode part.

42. The array substrate according to claim 29, further comprising: a gate line extending in the first direction, a data line extending in the second direction, a first common line distributed at one side of the gate line, and a second common line distributed at the other side of the gate line;
wherein the sub-pixel comprises: a first transistor, a second transistor, a third transistor electrically connected with one of the first transistor and the second transistor, and a first electrode part, a second electrode part, a third electrode part and a fourth electrode part that are sequentially distributed in the second direction;
wherein the first electrode part is electrically connected with one of the third electrode part and the fourth electrode part to form a first connection sub-pixel electrode; and the second electrode part is electrically connected with the other of the third electrode part and the fourth electrode part to form a second connection sub-pixel electrode;
in the sub-pixel row, the first connection sub-pixel electrodes of the plurality of sub-pixels are electrically connected with the first transistors and the second transistors alternately; the second connection sub-pixel electrodes of the plurality of sub-pixels are electrically connected with the first transistors and the second transistors alternately; and
in a same sub-pixel, the first connection sub-pixel electrode and the second connection sub-pixel electrode are electrically connected with different transistors.

43. The array substrate according to claim 42, wherein the first electrode part is electrically connected with the fourth electrode part, and the second electrode part is electrically connected with the third electrode part;
wherein the array substrate further comprises: first connecting parts and second connecting parts that extend in the second direction;
wherein one end of the first connecting part is electrically connected with the first electrode part, and the other end of the first connecting part is electrically connected with the fourth electrode part; and
one end of the second connecting part is electrically connected with the second electrode part, and the other end of the second connecting part is electrically connected with the third electrode part.

44. The array substrate according to claim 43, further comprising: first connecting convex portions connected with the first connecting parts and protruding toward a side of the third transistors; and
in the sub-pixel row, the first connecting convex portions are electrically connected with the first transistors and the second transistors alternately;
wherein extending lines of outer edges in the first direction of first connecting convex portions adjacent in the sub-pixel row do not coincide with each other.

45. The array substrate according to claim 43, wherein the first electrode part is electrically connected with the third electrode part, and the second electrode part is electrically connected with the fourth electrode part;
wherein the array substrate further comprises: third connecting parts and fourth connecting parts that extend in the second direction;
wherein an orthogonal projection of the third connecting part on the base substrate is located at a side of an orthogonal projection of the first sub-pixel electrode on the base substrate, one end of the third connecting part is electrically connected with the first electrode part, and the other end of the third connecting part is electrically connected with a side of the third electrode part facing the second electrode part; and
one end of the fourth connecting part is electrically connected with the second electrode part, and the other end of the fourth connecting part is electrically connected with the fourth electrode part.

46. The array substrate according to claim 29, wherein the plurality of sub-pixels comprise: sub-pixel columns extending in the second direction and arranged in the first direction; and
the main pixel portions and the auxiliary pixel portions are arranged alternately in the sub-pixel column; or two main pixel portions and two auxiliary pixel portions are arranged alternately in the sub-pixel column.

47. The array substrate according to claim 30, further comprising: a first electrode layer, wherein the first electrode layer comprises: a first electrode connecting part, a first hollowed-out structure, and a second hollowed-out structure;
an orthogonal projection of the first hollowed-out structure on the base substrate at least partially overlaps with an orthogonal projection of the first sub-pixel electrode on the base substrate; and
an orthogonal projection of the second hollowed-out structure on the base substrate at least partially overlaps with an orthogonal projection of the second sub-pixel electrode on the base substrate;
wherein an orthogonal projection of the first electrode connecting part on the base substrate covers an orthogonal projection of the data line on the base substrate.

48. A display panel, comprising:
the array substrate according to claim 29; and
an opposing substrate arranged opposite to the array substrate;
wherein a side of the opposing substrate facing the array substrate is provided with a common electrode layer.
